(19) United States
(12) Patent Application Publication
(10) Pub. No.: US 2012/0257170 A1
(43) Pub. Date: Oct. 11, 2012

(54) LIGHT-EMITTING DEVICE AND PROJECTOR

(75) Inventor: Masamitsu MOCHIZUKI, Fujimi (JP)

(73) Assignee: SEIKO EPSON CORPORATION, Tokyo (JP)

(21) Appl. No.: 13/439,048

(22) Filed: Apr. 4, 2012

(30) Foreign Application Priority Data
Apr. 6, 2011 (JP) 2011-084251

(51) Int. Cl. G03B 21/20; H01L 33/60

(52) U.S. Cl. 353/30; 257/98; 257/E33.072

(57) ABSTRACT

A light-emitting device includes a first layer that forms a waveguide of light and second and third layers that hold the first layer therebetween. The waveguide of the light includes a first region, a second region, and a third region. The first region includes a first portion having a curvature. The second region includes a second portion having a curvature. The first and second regions are connected in a reflecting section on a side surface of the first layer. The third region forms a resonator. A distance between the third region and at least one of the first and second regions is a distance at which evanescent coupling occurs. First light emitted from a light emitting area of the first region and second light emitted from a light emitting area of the second region are emitted in the same direction.

### BACKGROUND

1. Technical Field

The present invention relates to a light-emitting device and a projector.

2. Related Art

A super luminescent diode (hereinafter also referred to as “SLD”) is a semiconductor light-emitting device that can output several hundreds of milliwatts with a single component in the same manner as a semiconductor laser, while showing a broad spectrum and thus being incoherent in the same manner as a normal light-emitting diode.

The SLD can be used, for example, for a light source of a projector. However, in order to realize a projector having a small size and high luminance, it is necessary to use a light source having a large optical output and small etendue. Therefore, it is desirable that lights emitted from plural gain regions travel in the same direction. In JP-A-2010-192603, a gain region having a linear shape and a gain region having an arc shape are combined, whereby lights emitted from light emitting areas of the two gain regions are allowed to travel in the same direction.

To reduce a loss of an optical system and the number of components, a type of a projector that can perform light condensing and uniform illumination simultaneously by arranging an SLD right just below a light valve and using a lens array. In the projector of that type, it is necessary to arrange light emitting areas according to an interval of the lens array.

In the technique described in JP-A-2010-192603, as a method of making a distance between the two light emitting areas large according to a lens array, for example, it is conceivable to tilt the linear gain region large with respect to the perpendicular of a surface of the light emitting area. However, in such a method, it is likely that an incident angle on the surface of the light emitting area of the light generated in the linear gain region increases and a radiation pattern is deteriorated. As a result, it is sometimes difficult to uniformly illuminate the light valve.

As another method of making the distance between the two light emitting areas large, it is also conceivable to increase the total lengths of the gain regions. However, when the total length of the gain regions is large, in general, although it is possible to realize an increase in an output, a very large current has to be injected to obtain the so-called population inversion. As a result, unless the light emitting device is used at an optical output unnecessarily higher than a predetermined optical output, improvement of efficiency cannot be realized. In other words, light emission efficiency is deteriorated at an optical output equal to or smaller than the predetermined optical output. When the light emission efficiency is deteriorated, it is difficult to exhaust heat from a light-emitting device. Therefore, for example, it is difficult to realize a small projector. Further, when the total length of the gain regions is large, the area of an entire light-emitting component is large. As a result, for example, resources are wasted and manufacturing costs increase.

### SUMMARY

An advantage of some aspects of the invention is to provide a light-emitting device that has a satisfactory radiation pattern and can make distances between plural light emitting areas larger while realizing a reduction in the size and an increase in the output of the light-emitting device. Another advantage of some aspects of the invention is to provide a projector including the light-emitting device.

### Application Example 1

A light-emitting device according to the application example of the invention includes a first layer that generates light by an injection current and form a waveguide of the light; second and third layers that hold the first layer therebetween and suppress a leak of the light; and an electrode that injects the injection current into the first layer. The waveguide of the light obtained by the injection current includes a belt-like first region, a belt-like second region and a belt-like third region. The first region includes a first portion having a curvature. The second region includes a second portion having a curvature. The first and second regions are connected in a reflecting section on a reflection surface provided on a side surface of the first layer. The third region forms a resonator. A distance between the third region and at least one of the first and second regions is a distance at which evanescent coupling occurs. First light is emitted from a first light emitting area of the first region on an emission surface provide on a side surface of the first layer opposed to the reflection surface, second light is emitted from a second light emitting area of the second region on the emission surface. The first light and the second light are emitted in the same direction.

With such a light-emitting device, it is possible to make a distance between an end face of the first region on the emission surface and an end face of the second region on the emission surface (a distance between the first and second emitting areas) larger without increasing an incident angle of the lights guided in the first and second regions on the emitting surface. Consequently, it is possible to suppress a radiation pattern of the emitted lights from being distorted. For example, when the light-emitting device is used for a light source of a projector, it is possible to uniformly illuminate a light valve.

Further, with such a light-emitting device, compared with an example in which a linear gain region is used from the reflection surface to the emission surface, the distance between the first and second light emitting areas can be made larger without increasing the total length of gain regions. Therefore, it is unnecessary to inject a very large current and it is possible to suppress power consumption. Consequently, since it is easy to exhaust heat from the light-emitting device, for example, when the light-emitting device is used for a light source of a projector, it is possible to realize a reduction in a housing size of the projector. Further, since the total length of the gain regions does not have to be increased, it is possible to realize a reduction in the size of the entire light-emitting device. Therefore, resources are not wasted and it is possible to suppress manufacturing costs.

Moreover, with such a light-emitting device, a third region is formed along the first or second region. Light generated in the third region couples with the lights guided in the first and second regions while resonating in the third region. The coupled light is guided in the first and second regions and emitted from the end face of the first or second region on the emission surface. Accordingly, although a distance between the first and second light emitting areas is the same as the distance formed when the third region is not formed, it is possible to realize an increase in an output compared with the output obtained when the third region is not formed. Therefore, for example, when the light-emitting device is used for a light source of a projector, it is possible to realize an increase in luminance of the projector.

As explained above, in such a light-emitting device, a radiation pattern is satisfactory and it is possible to make the distance between the first and second emitting areas large while realizing a reduction in the size and an increase in the output of the light-emitting device.

### Application Example 2

In the light-emitting device according to the above application example, it is preferred that the first region is connected to the reflecting section while tilting at a first angle with respect to a perpendicular of the reflection surface. The second region is connected to the reflecting section while tilting at a second angle with respect to the perpendicular. The first angle and the second angle are equal to or larger than the critical angle and are the same size.

With such a light-emitting device, the reflecting section can totally reflect the lights generated in the first region and second regions. Therefore, it is possible to suppress an optical loss in the reflecting section and efficiently reflect the lights.

### Application Example 3

In the light-emitting device according to the above application examples, it is preferred that the first region includes a third portion linearly provided from the first portion to the emission surface. The second region includes a fourth portion linearly provided from the second portion to the emission surface.

With such a light-emitting device, a radiation pattern is satisfactory and it is possible to make the distance between the first and second light emitting areas large while realizing a reduction in the size of the light-emitting device.

### Application Example 4

In the light-emitting device according to the above application examples, it is preferred that the first region includes a fifth portion linearly provided from the reflecting section to the first portion. The second region includes a sixth portion linearly provided from the reflecting section to the second portion.

With such a light-emitting device, it is possible to more surely make the light generated in the first region and reflected in the reflecting section enter the second region and more surely make the light generated in the second region and reflected in the reflection section enter the first region.

### Application Example 5

In the light-emitting device according to the above application examples, it is preferred that the first and second portions have an arc shape viewed from a stacking direction of the first layer and the second layer.

With such a light-emitting device, a radiation pattern is satisfactory and it is possible to make the distance between the first and second light emitting areas large while realizing a reduction in the size of the light-emitting device.

### Application Example 6

In the light-emitting device according to the above application examples, it is preferred that the third region includes reflection surfaces at both ends in a longitudinal direction thereof.

With such a light-emitting device, it is possible to couple light resonating in the third region with the lights guided in the first and second regions and emit the coupled light from the end face of the first region or the second region on the emission surface. Therefore, a radiation pattern is satisfactory and it is possible to make the distance between the first and second light emitting areas large while realizing a reduction in the size and an increase in the output of the light-emitting device.

### Application Example 7

In the light-emitting device according to the above application example, it is preferred that the third region includes a periodic structure composing a resonator of a distributed feedback type therein.

With such a light-emitting device, it is possible to more surely couple light resonating in the third region with the lights guided in the first and second regions and emit the coupled light from the end face of the first region or the second region on the emission surface. Therefore, a radiation pattern is satisfactory and it is possible to make the distance between the first and second light emitting areas large while realizing a reduction in the size and an increase in the output of the light-emitting device.

### Application Example 8

In the light-emitting device according to the above application example, it is preferred that the third region includes resonators employing distributed Bragg reflector at both ends in a longitudinal direction thereof.

With such a light-emitting device, it is possible to more surely couple lights in a large number of resonance modes resonating in the third region with the lights guided in the first and second regions and emit the coupled light from the end face of the first region or the second region on the emission surface. Therefore, a radiation pattern is satisfactory and it is possible to make the distance between the first and second light emitting areas large while realizing a reduction in the size and an increase in the output of the light-emitting device and realizing improvement of incoherent properties.

### Application Example 9

In the light-emitting device according to the above application examples, it is preferred that a distance between the third region and the first or second region is fixed.

With such a light-emitting device, it is possible to efficiently couple light resonating in the third region with the light guided in the first or second region. Therefore, a radiation pattern is satisfactory and it is possible to make the distance between the first and second light emitting areas large while realizing a reduction in the size and an increase in the output of the light-emitting device.

### Application Example 10

In the light-emitting device according to the above application examples, it is preferred that the third region and the first or second region are parallel.

With such a light-emitting device, it is possible to efficiently couple light resonating in the third region with the light guided in the first or second region. Therefore, a radiation pattern is satisfactory and it is possible to make the distance between the first and second light emitting areas large while realizing a reduction in the size and an increase in the output of the light-emitting device.

### Application Example 11

In the light-emitting device according to the above application examples, it is preferred that a plurality of the third regions are provided.

With such a light emitting device, a radiation pattern is satisfactory and it is possible to make the distance between the first and second light emitting areas large while realizing a reduction in the size and an increase in the output of the light-emitting device.

### Application Example 12

In the light-emitting device according to the above application examples, it is preferred that the third region includes a waveguide structure of an index-guiding type.

With such a light-emitting device, it is possible to more surely make light generated in the third region resonate in the third region. Therefore, a radiation pattern is satisfactory and it is possible to make the distance between the first and second light emitting areas large while realizing a reduction in the size and an increase in the output of the light-emitting device.

### Application Example 13

In the light-emitting device according to the above application examples, it is preferred that the first and second regions include a waveguide structure of an index-guiding type.

With such a light-emitting device, it is possible to more surely make the coupled light, the light having coupled with the light guided in the first and second regions, guided in the first and second region. Therefore, a radiation pattern is satisfactory and it is possible to make the distance between the first and second light emitting areas large while realizing a reduction in the size and an increase in the output of the light-emitting device.

### Application Example 14

In the light-emitting device according to the above application examples, it is preferred that a fourth layer is formed on a side of the third layer opposite to the first layer side. The light-emitting device includes a first electrode electrically connected to the second layer and a second electrode electrically connected to the third layer and in contact with the fourth layer. The shape of the first, second, and third regions is the same as the shape of a contact surface of the fourth layer and the second electrode. The fourth layer is a layer in ohmic contact with the second electrode.

With such a light-emitting device, it is possible to reduce the resistance of the light-emitting device. This makes it possible to suppress power consumption and makes it easy to exhaust heat from the light-emitting device. Therefore, for example, when the light-emitting device is used for a light source of a projector, it is possible to realize a reduction in a housing size of the projector.

In the description related to the invention, the word “electrically connected” is used in such a manner that ‘a specific member (hereinafter referred to as “A member”) is “electrically connected” to another specific member (hereinafter referred to as “B member”)’. In the description related to the invention, the word “electrically connected” is used so that the word includes a case in which the A member and the B member are directly in contact and electrically connected and a case in which the A member and the B member are electrically connected via another member.

### Application Example 15

In the light-emitting device according to the above application examples, it is preferred that the side surface on which the reflecting section is provided is a cleavage plane.

With such a light-emitting device, for example, compared with the case in which the reflecting section is formed by a photolithography technique and an etching technique, it is possible to accurately form the reflecting section and reduce light scattering at an end face. Therefore, it is possible to suppress an optical loss in the reflecting section and efficiently reflect light.

### Application Example 16

This application example of the invention is a projector including the light-emitting device explained above; a micro lens that condenses light emitting from the light-emitting device; a light modulating device that modulates the light condensed by the micro lens according to image information; and a projecting device that projects an image formed by the light modulating device.

With such a configuration of the projector, it is possible to provide a small projector having high luminance.

### BRIEF DESCRIPTION OF THE DRAWINGS

The invention will be described with reference to the accompanying drawings, wherein like numbers reference like elements.

FIG. 1 is a plan view schematically showing a light-emitting device according to an embodiment.

FIG. 2 is a sectional view schematically showing the light-emitting device according to the embodiment.

FIG. 3 is a sectional view schematically showing grooves of the light-emitting device according to the embodiment.

FIG. 4 is a sectional view schematically showing a manufacturing process for the light-emitting device according to the embodiment.

FIG. 5 is a sectional view schematically showing the manufacturing process for the light-emitting device according to the embodiment.

FIG. 6 is a plan view schematically showing a light-emitting device according to a first modification of the embodiment.

FIG. 7 is a plan view schematically showing a light-emitting device according to a second modification of the embodiment.

FIG. 8 is a sectional view schematically showing the light-emitting device according to the second modification of the embodiment.

FIG. 9 is a sectional view schematically showing the light-emitting device according to the second modification of the embodiment.

FIG. 10 is a plan view schematically showing a light-emitting device according to a third modification of the embodiment.

FIG. 11 is a sectional view schematically showing the light-emitting device according to the third modification of the embodiment.

FIG. 12 is a plan view schematically showing a light-emitting device according to a fourth modification of the embodiment.

FIG. 13 is a sectional view schematically showing the light-emitting device according to the fourth modification of the embodiment.

FIGS. 14A and 14B are graphs schematically showing spectrum shapes of lights output from the light-emitting device according to the third modification of the embodiment and the light-emitting device according to the fourth modification of the embodiment.

FIG. 15 is a plan view schematically showing a light-emitting device according to a fifth modification of the embodiment.

FIG. 16 is a plan view schematically showing a light-emitting device according to a sixth modification of the embodiment.

FIG. 17 is a diagram schematically showing a projector according to the embodiment.

FIG. 18 is a diagram schematically showing the projector according to the embodiment.

FIG. 19 is a diagram schematically showing a light source of the projector according to the embodiment.

FIG. 20 is a sectional view schematically showing the light source of the projector according to the embodiment.

FIG. 21 is a sectional view schematically showing the light source of the projector according to the embodiment.

FIG. 22 is a sectional view schematically showing the light source of the projector according to the embodiment.

### DESCRIPTION OF EXEMPLARY EMBODIMENTS

Exemplary embodiments of the invention are explained below with reference to the accompanying drawings.

### 1. Light-Emitting Device

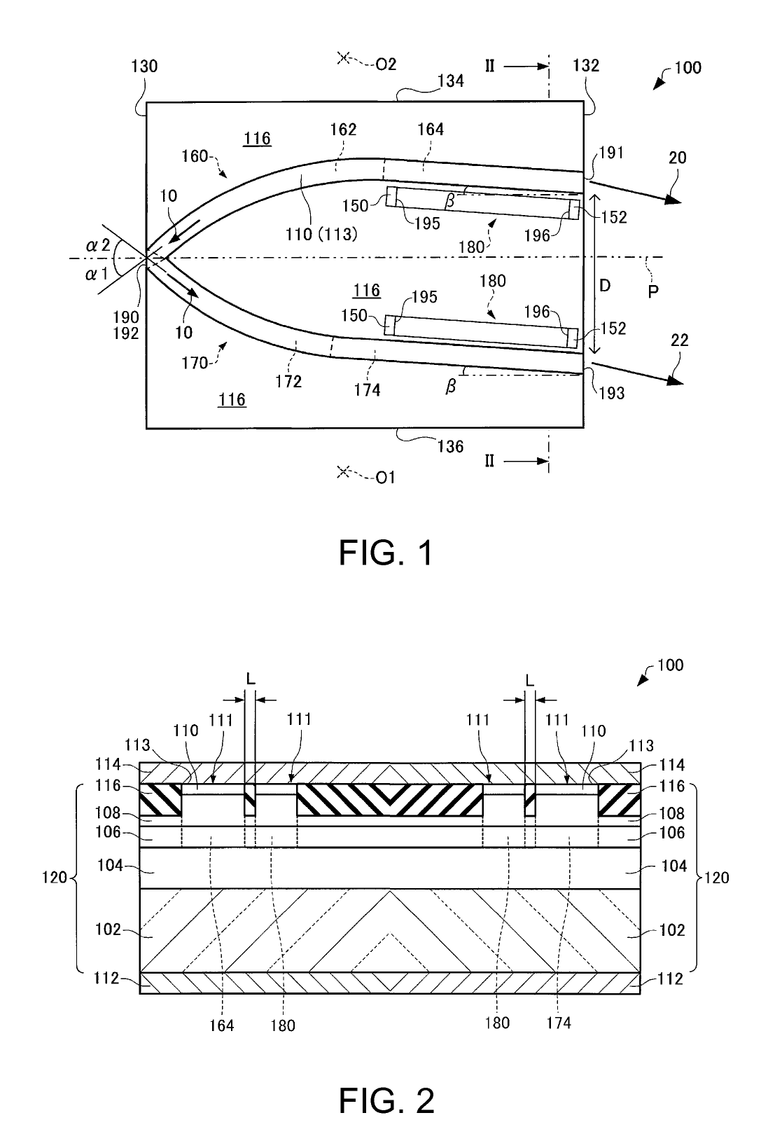

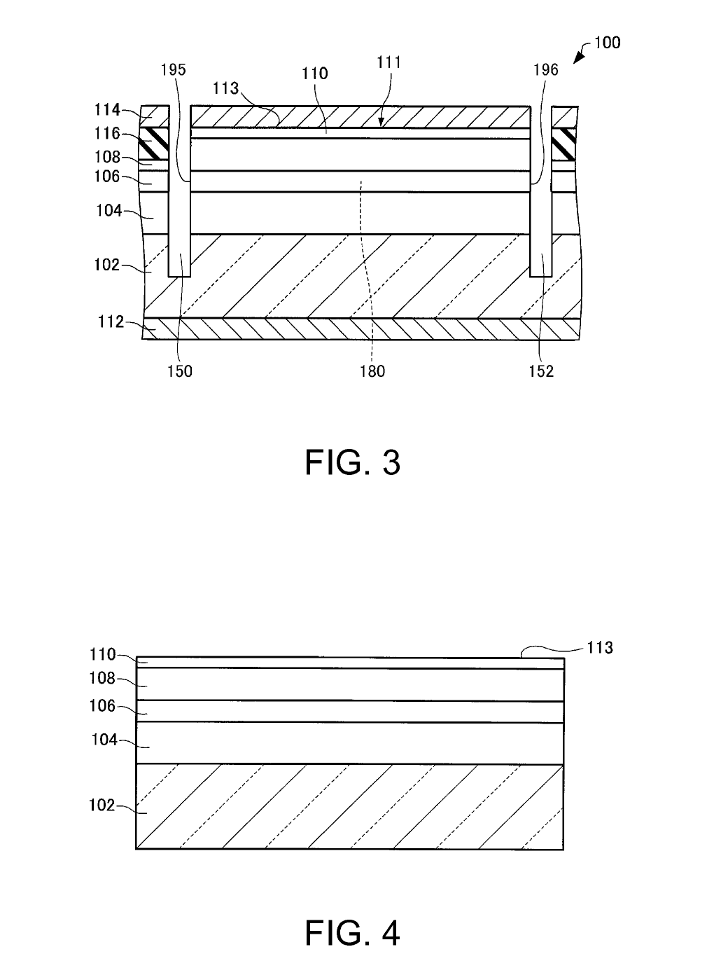

First, a light-emitting device according to an embodiment is explained with reference to the accompanying drawings. FIG. 1 is a plan view schematically showing a light-emitting device 100 according to this embodiment. FIG. 2 is a sectional view taken along line II-II in FIG. 1 schematically showing the light-emitting device 100 according to this embodiment. FIG. 3 is a sectional view along with the longitudinal direction of a third region 180 in FIG. 1 schematically showing the third region 180 and grooves 150, 152 of the light-emitting device 100 according to this embodiment. In FIG. 1, for convenience of illustration, a second electrode 114 is not shown.

In the following explanation, the light-emitting device 100 is made of an InGaAlP (red) material system. The light-emitting device 100 includes a region that forms an SLD and a region that forms an optical resonator. Unlike a semiconductor laser, the SLD has wide-band emission spectra. Therefore, the SLD can reduce speckle noise.

As shown in FIGS. 1 and 2, the light-emitting device 100 can include a laminated body 120, a first electrode 112, and a second electrode 114.

The laminated body 120 can include a substrate 102, a second layer 104 (hereinafter also referred to as “first cladding layer 104”), a first layer 106 (hereinafter also referred to as “active layer 106”), a third layer 108 (hereinafter also referred to as “second cladding layer 108”), a fourth layer 110 (hereinafter also referred to as “contact layer 110”), and an insulating layer 116. The shape of the laminated body 120 is, for example, a rectangular parallelepiped (including a cube).

As the substrate 102, for example, a GaAs substrate of a first conduction type (e.g., an n-type) can be used.

The first cladding layer 104 is formed on the substrate 102. As the first cladding layer 104, for example, an n-type InGaAlP layer can be used. Although not shown in the figures, a buffer layer may be formed between the substrate 102 and the first cladding layer 104. As the buffer layer, for example, an n-type GaAs layer, an AlGaAs layer, or an InGaP layer can be used. The buffer layer can improve crystal quality of layers formed above the buffer layer.

The active layer 106 is formed on the first cladding layer 104. The active layer 106 is held between the first cladding layer 104 and the second cladding layer 108. The active layer 106 includes, for example, a multiple quantum well (MQW) structure obtained by stacking three quantum well structures including an InGaP well layer and an InGaAlP barrier layer.

The shape of the active layer 106 is, for example, a rectangular parallelepiped (including a cube). The plane shape of the active layer 106 is, for example, the same as the plane shape of the laminated body 120. As shown in FIG. 1, the active layer 106 can include a first surface 130, a second surface 132, a third surface 134, and a fourth surface 136. The surfaces 130, 132, 134, and 136 are the surfaces of the active layer 106, do not have in plane contact with the first cladding layer 104 or the second cladding layer 108 and forms the external shape of the laminated body 120. The surfaces 130, 132, 134, and 136 can also be considered side surfaces of the active layer 106 and are flat surfaces. The first surface 130 and the second surface 132 are opposed to each other and parallel to each other in an example shown in the figures. The third surface 134 and the fourth surface 136 are surfaces connected to the first surface 130 and the second surface 132, opposed to each other, and parallel to each other in the example shown in the figure.

The first surface 130 can be a surface formed by cleavage. A method of forming the second surface 132 is not specifically limited as long as the second surface 132 is opposed to the first surface 130. For example, when the second surface 132 is also formed by cleavage, it is possible to easily oppose the second surface 132 to the first surface 130.

Part of the active layer 106 forms a first gain region (a first region) 160, a second gain region (a second region) 170, and a third gain region (a third region) 180. The gain regions 160, 170, and 180 can generate lights. The lights generated in the gain regions 160 and 170 can be guided in the gain regions 160 and 170 while receiving gains. The light generated in the gain region 180 can couple with the lights guided in the gain regions 160 and 170 while resonating in the gain region 180 and can be guided in the gain regions 160 and 170.

As shown in FIG. 1, the gain regions 160 and 170 are provided from the first surface 130 to the second surface 132. Specifically, the first gain region 160 includes a first end face 190 provided on the first surface 130 and a second end face 191 provided on the second surface 132. The second gain region 170 includes a third end face 192 provided on the first surface 130 and a fourth end face 193 provided on the second surface 132.

The first end face 190 of the first gain region 160 and the third end face 192 of the second gain region 170 overlap each other on the first surface 130. In the example shown in the figure, the first end face 190 and the third end face 192 completely overlap each other. On the other hand, the second end face 191 of the first gain region 160 and the fourth end face 193 of the second gain region 170 are apart from each other with a distance D on the second surface 132.

As shown in FIG. 1, the first gain region 160 is connected to the first surface 130 while tilting to one side (e.g., the third surface 134 side) with respect to a perpendicular P of the first surface 130 viewed from the stacking direction of the laminated body 120 (in plan view). More specifically, the first gain region 160 is connected to the first surface 130 while tilting at a first angle α1 with respect to the perpendicular P. The second gain region 170 is connected to the first surface 130 while tilting to the other side (e.g., the fourth surface 136 side) with respect to the perpendicular P in plan view. More specifically, the second gain region 170 is connected to the first surface 130 while tilting at a second angle α2 with respect to the perpendicular P.

The first angle 1 can also be considered an incident angle of light generated in the first gain region 160 on the first surface 130. The second angle α2 can also be considered an incident angle of light generated in the second gain region 170 on the first surface 130.

In the example shown in the figure, the first angle α1 and the second angle α2 are acute angles of the same size and are equal to or larger than the critical angle. Consequently, the first surface 130 can totally reflect the lights generated in the gain regions 160 and 170.

The first gain region 160 and the second gain region 170 are connected to the second surface 132 while tilting at the same inclination. More specifically, the gain regions 160 and 170 are connected to the second surface 132 while tilting at a third angle β with respect to the perpendicular P. The third angle β may be 0 degree as long as the third angle β is an acute angle and smaller than the critical angle. Consequently, light 20 emitted from the second end face 191 of the first gain region 160 and light 22 emitted from the fourth end face 193 of the second gain region 170 can travel in the same direction. The end faces 191 and 193 can be considered light emitting areas.

The third angle β can also be considered an incident angle of the lights generated in the gain region 160 and 170 on the second surface 132.

By setting the angles α1 and α2 to be equal to or larger than the critical angle and setting the angle β to be smaller than the critical angle, it is possible to set the reflectance of the first surface 130 to be higher than the reflectance of the second surface 132 in a wavelength band of the lights generated in the gain regions 160 and 170. In other words, the first surface 130 can be a reflection surface and the second surface 132 can be an emission surface.

Although not shown in the figure, for example, the first surface 130 may be covered with a reflection film and the second surface 132 can be covered with an antireflection film. Consequently, in the wavelength band of the lights generated in the gain regions 160 and 170, the reflectance of the first surface 130 can also be set to be higher than the reflectance of the second surface 132. As the reflection film and the antireflection film, an SiO₂ layer, a Ta₂O₅ layer, an Al₂O₃ layer, a TiN layer, a TiO₂ layer, an SiON layer, an SiN layer, a multilayer film of these layers, or the like can be used.

Further, the third angle β can be an angle larger than 0 degree or the second surface 132 can be covered with the antireflection film. Consequently, it is possible to prevent multiple reflections of the lights generated in the gain regions 160 and 170 between the second end face 191 and the fourth end face 193. As a result, a direct resonator can be prevented from being formed. Therefore, it is possible to suppress or prevent laser oscillation of the lights generated in the gain regions 160 and 170. In other words, the gain regions 160 and 170 can form an SLD region. If the third angle β is 0 degree and the second surface is not covered with the antireflection film, the lights are repeatedly reflected between the end faces 191 and 193 via the first surface 130 and a resonator is formed.

The first gain region 160 includes a first gain portion (a first portion) 162. Similarly, the second gain region 170 includes a second gain portion (a second portion) 172.

The first gain portion 162 and the second gain portion 172 are connected to the first surface 130, for example. In other words, the first gain portion 162 composes the first end face 190 of the first gain region 160 and the second gain portion 172 composes the third end face 192 of the second gain region 170.

The first gain portion 162 has a shape having a first curvature in plan view as shown in FIG. 1. The second gain portion 172 has a shape having a second curvature in plan view. The first curvature and the second curvature may be the same value or may be different values. In the example shown in the figure, the first gain portion 162 and the second gain portion 172 have an arc shape and have the same curvature radius. As shown in FIG. 1, the length of the arc of the second gain portion 172 may be smaller than the length of the arc of the first gain portion 162. For example, the first gain portion 162 has a shape of an arc around a point O1. The second gain portion 172 has a shape of an arc around a point O2. The point O1 is located at the fourth surface 136 side with respect to the perpendicular P that passes the end faces 190 and 192. The point O2 is located at the third surface 134 side with respect to the perpendicular P.

Lights generated in the gain regions 160 and 170 can travel in the arc-shaped gain portions 162 and 172 according to a difference between the effective refractive index of the vertical cross section of the laminated body 120 including the gain portions 162 and 172 (hereinafter simply referred to as “effective refractive index of the gain portions 162 and 172”) and the effective refractive index of the vertical cross section of the laminated body 120 excluding the gain regions 160 and 170 (hereinafter simply referred to as “effective refractive index of a portion excluding the gain regions 160 and 170”).

The curvature radius of the gain portions 162 and 172 is, for example, equal to or larger than 800 μm depending on the difference between the effective refractive index of the gain portions 162 and 172 and the effective refractive index of the portion excluding the gain regions 160 and 170. When the curvature radius of the gain portions 162 and 172 is smaller than 800 μm, in some case, the lights in the gain portions 162 and 172 cannot be efficiently guided. The curvature radius of the gain portions 162 and 172 is desirably more than 1600 μm. Consequently, it is possible to efficiently guide the lights in the gain portions 162 and 172 without unnecessarily making the entire light-emitting device 100 large.

The first gain region 160 can further includes a third gain portion (a third portion) 164. Similarly, the second gain region 170 can further include a fourth gain portion (a fourth portion) 174.

The third gain portion 164 is linearly provided from the first gain portion 162 to the second surface 132. In other words, the third gain portion 164 composes the second end face 191 of the first gain region 160. The third gain portion 164 is smoothly connected to the arc-shaped first gain portion 162. For example, the third gain portion 164 is provided to be parallel to a tangent at a point on a boundary between the gain portions 162 and 164. The third gain portion 164 tilts at a third angle β (including 0 degree) with respect to the perpendicular P.

The fourth gain portion 174 is linearly provided from the second gain portion 172 to the second surface 132. In other words, the fourth gain portion 174 composes the fourth end face 193 of the second gain region 170. The fourth gain portion 174 is smoothly connected to the arc-shaped second gain portion 172. For example, the gain portion 174 is provided to be parallel to a tangent at a point on a boundary between the gain portions 172 and 174. The fourth gain portion 174 tilts at the third angle β (including 0 degree) with respect to the perpendicular P. The third gain portion 164 and the fourth gain portion 174 are parallel to each other. As shown in FIG. 1, the length of the fourth gain portion 174 may be larger than the length of the third gain portion 164.

The third gain region 180 can be linearly provided from a fifth end face 195 to a sixth end face 196 along the third gain portion 164 of the first gain region 160 or the fourth gain portion 174 of the second gain region 170. In the example shown in FIG. 1, two third gain regions 180 are formed. However, the number of third gain regions 180 is not specifically limited. In the example shown in FIG. 1, as seen from the stacking direction of the laminated body 120, the third gain regions 180 are formed on the fourth surface side of the first gain region 160 along the first gain region 160 and the third surface side of the second gain region 170 along the second gain region 170.

The fifth end face 195 and the sixth end face 196 are surfaces formed of at least the contact layer 110 and part of the second cladding layer 108 explained later. The fifth end face 195 and the sixth end face 196 can be formed by forming a first groove 150 and a second groove 152. Light generated in the third gain region 180 can be reflected according to a difference between the effective refractive index of the third gain region 180 and the effective refractive index of the vertical cross section of the laminated body 120 including the first groove 150 and the second groove 152 (hereinafter simply referred to as “effective refractive index of the grooves 150 and 152”).

The fifth end face 195 and the sixth end face 196 can be formed perpendicularly to the extending direction of the third gain region 180 viewed from the stacking direction of the laminating body 120 (in plan view). Consequently, the light generated in the third gain region 180 can be repeatedly reflected between the fifth end face 195 and the sixth end face 196. In other words, the third gain region 180 can form an optical resonator. The light generated in the third gain region 180 can couple with the lights guided in the gain regions 160 and 170 while resonating in the third gain region 180 and can be guided in the gain regions 160 and 170.

In order to make the light efficiently resonate between the fifth end face 195 and the sixth end face 196, it is desirable that the reflectance of the fifth end face 195 and the sixth end face 196 is high. When it is taken into account that the light is reflected by providing a predetermined difference between the effective refractive index of the third gain region 180 and the effective refractive index of the grooves 150 and 152, the fifth end face 195 is desirably formed of not only the contact layer 110 and the second cladding layer 108 but also the active layer 106, the first cladding layer 104, and part of the substrate 102.

In the example shown in FIG. 1, the third gain region 180 is formed to tilt at the same inclination as that of the third gain portion 164 and the fourth gain portion 174. In other words, the third gain region 180 is provided in parallel to the third gain portion 164 and the fourth gain portion 174. More specifically, the gain region 180 is formed to tilt at the third angle β (including 0 degree) with respect to the perpendicular P of the second surface. Consequently, the light generated in the third gain region 180 and resonating in the third gain region 180 can efficiently couple with the lights guided in the first gain region 160 and the second gain region 170.

In order to cause the light resonating in the third gain region 180 to efficiently couple with the lights guided in the first gain region 160 and the second gain region 170, a distance L between the first and second gain regions 160 and 170 and the third gain region 180 formed along the first and second gain regions 160 and 170 is, for example, 100 nm to about a double of the width of the gain regions (several micrometers to several tens micrometers) depending on the effective refractive indexes of the gain regions and the portion excluding the gain regions. For example, if the distance L is smaller than 100 nm, in some case, the lights traveling in the first gain region 160 and the second gain region 170 also resonate. If the distance L is larger than the double of the width of the gain regions, in some case, the lights do not sufficiently couple.

The coupled light can be guided in the first and second gain regions 160 and 170 while receiving gains and emitted from the second end face 191 and the fourth end face 193 provided on the second surface 132. In other words, the second face 132 is the emission surface of the lights generated in the first gain region 160 and the second gain region 170 and, at the same time, can be an emission surface of the light generated in the third gain region 180.

The third gain region 180 may be formed on the third surface side of the first gain region 160 or the fourth surface side of the second gain region 170. Only one third gain region 180 may be formed. The third gain regions 180 may be formed on both the third surface side and the fourth surface side along each of the first gain region 160 and the second gain region 170. It is possible to increase the output of the light-emitting device 100 by forming plural third gain regions 180.

The number of third gain regions 180 formed along the first gain region 160 and the number of third gain regions 180 formed along the second gain region 170 may be different from each other or may be the same. The lengths of the plural third gain regions 180 may be different from one another or may be the same. The intensity of the light 20 emitted from the second end face 191 and the intensity of the light 22 emitted from the fourth end face 193 can be close to each other when the number and the length of the third gain regions 180 formed along the first gain region 160 are the same as the number and the length of the third gain regions 180 formed along the second gain region 170.

As shown in FIG. 2, the second cladding layer 108 is formed on the active layer 106. As the second cladding layer 108, for example, an InGaAlP layer of a second conduction type (e.g., a p-type) can be used.

For example, a pin diode is composed by the p-type second cladding layer 108, the active layer 106 not doped with impurities, and the n-type first cladding layer 104. Each of the first cladding layer 104 and the second cladding layer 108 is a layer having forbidden band gap larger than the forbidden band gap of the active layer 106 and having a refractive index smaller than the refractive index of the active layer 106. The active layer 106 has a function of generating light and guiding the light while amplifying the light. The first cladding layer 104 and the second cladding layer 108 hold the active layer 106 therebetween and have a function of confining an injected carrier (electrons and holes) and light (a function of suppressing a leak of light).

In the light-emitting device 100, when a forward bias voltage of the pin diode is applied between the first electrode 112 and the second electrode 114, recombination of the electrons and the holes occurs in the gain regions 160, 170, and 180 of the active layer 106. Light is generated by the recombination. Starting from the generated light, stimulated emission occurs and the intensity of the light is amplified in the gain regions 160, 170, and 180.

For example, as shown in FIG. 1, a part 10 of light generated in the first gain region 160 is amplified in the first gain region 160 and, then, reflected on the first surface 130 and emitted from the fourth end face 193 of the second gain region 170 as the light 22. Its light intensity is also amplified in the second gain region 170 after the reflection. Similarly, part of light generated in the second gain region 170 is amplified in the second gain region 170 and, then, reflected on the first surface 130 and emitted from the second end face 191 of the first gain region 160 as the light 20. Its light intensity is also amplified in the first gain region 160 after the reflection.

Some light generated in the first gain region 160 is directly emitted from the second end face 191 as the light 20. Similarly, some light generated in the second gain region 170 is directly emitted from the fourth end face 193 as the light 22. These lights are also amplified in the gain region 160 or 170 in the same manner.

Light generated in the third gain region 180 formed along the first gain region 160 is amplified while repeating multiple reflections between the fifth end face 195 and the sixth end face 196 in the third gain region 180 and, then, couples with the light guided in the first gain region 160. Part of the coupled light is amplified in the first gain region 160 and, then, reflected on the first surface 130 and emitted from the fourth end face 193 of the second gain region 170 as the light 22. Its light intensity is also amplified in the second gain region 170 after the reflection. Some coupled light is emitted from the second end face 191 as the light 20. Its light is also amplified in the first gain region 160 in the same manner.

Similarly, light generated in the third gain region 180 formed along the second gain region 170 is amplified while repeating multiple reflections between the fifth end face 195 and the sixth end face 196 in the third gain region 180 and, then, couples with the light guided in the second gain region 170. Part of the coupled light is amplified in the second gain region 170 and, then, reflected on the first surface 130 and emitted from the second end face 191 of the first gain region 160 as the light 20. Its light intensity is also amplified in the first gain region 160 after the reflection. Some coupled light is emitted from the fourth end face 193 as the light 22. Its light is also amplified in the second gain region 170 in the same manner.

As shown in FIG. 2, the contact layer 110 is formed on the second cladding layer 108. In other words, the contact layer 110 is considered to be formed on the opposite side of the second cladding layer 108 to the active layer 106 side. The contact layer 110 can be in ohmic contact with the second electrode 114. An upper surface 113 of the contact layer 110 is considered a contact surface between the contact layer 110 and the second electrode 114. As the contact layer 110, for example, a p-type GaAs layer can be used.

The contact layer 110 and part of the second cladding layer 108 can form columnar sections 111. A plane shape of the columnar sections 111 is the same as a plane shape of the gain regions 160, 170, and 180. In other words, a plane shape of the upper surface 113 of the contact layer 110 is considered the same as the plane shape of the gain regions 160, 170, and 180. For example, a current path between the electrodes 112 and 114 is determined by the plane shape of the columnar sections 111 and, as a result, the plane shape of the gain regions 160, 170, and 180 is determined. Although not shown in the figure, side surfaces of the columnar sections 111 can be inclined.

The insulating layer 116 can be formed at sides of the columnar sections 111 on the second cladding layer 108. The insulating layer 116 can be in contact with the side surfaces of the columnar sections 111. The upper surface of the insulating layer 116 can be continuous to the upper surface 113 of the contact layer 110, for example. As the insulating layer 116, for example, an SiN layer, an SiO₂ layer, an SiON layer, an Al₂O₃ layer, or a polyimide layer can be used.

When the material explained above is used as the insulating layer 116, a current between the electrodes 112 and 114 can flow through the columnar sections 111 formed between the insulating layers 116 avoiding the insulating layer 116. The insulating layer 116 can have a refractive index smaller than the refractive index of the second cladding layer 108. In this case, the effective refractive index of the vertical cross section of portions where the insulating layer 116 is formed is smaller than the effective refractive index of the vertical cross section of portions where the insulating layer 116 is not formed, i.e., portions where the columnar sections 111 are formed. Consequently, in the plane direction, it is possible to efficiently confine light in the gain regions 160, 170, and 180. Although not shown in the figure, it is also possible that the insulating layer 116 is not provided. In this case, an air surrounding the columnar part 111 can function as the insulating layer 116.

The first electrode 112 is formed on the entire lower surface of the substrate 102. The first electrode 112 can be in contact with a layer (in the example shown in the figure, the substrate 102) that is in ohmic contact with the first electrode 112. The first electrode 112 is electrically connected to the first cladding layer 104 via the substrate 102. The first electrode 112 is one electrode for driving the light-emitting device 100. As the first electrode 112, for example, a layer obtained by stacking a Cr layer, an AuGe layer, an Ni layer, and an Au layer from the substrate 102 side in this order can be used.

A second contact layer (not shown) can be provided between the first cladding layer 104 and the substrate 102 and exposed by dry etching or the like. The first electrode 112 can be provided on the second contact layer. Consequently, a single-sided electrode structure can be obtained. This formation is particularly effective when the substrate 102 is insulative.

The second electrode 114 is formed in contact with the upper surface 113 of the contact layer 110. As shown in FIG. 2, the second electrode 114 may also be formed on the insulating layer 116. The second electrode 114 is electrically connected to the second cladding layer 108 via the contact layer 110. The second electrode 114 is the other electrode for driving the light-emitting device 100. As the second electrode 114, for example, a layer obtained by stacking a Cr layer, an AuZn layer, and an Au layer from the contact layer 110 side in this order can be used.

As an example of the light-emitting device 100 according to this embodiment, the InGaAlP based light-emitting device is explained above. However, as the light-emitting device 100, any material which can form gain regions can be used. As a semiconductor material, for example, AlGaN, GaN, InGaN, GaAs, AlGaAs, InGaAs, InGaAsP, ZnCdSe, or the like can be used.

In the example explained above, the light-emitting device 100 of a so-called index-guiding type is explained. However, the light-emitting device 100 may be a so-called gain-guiding type. More specifically, one or all of the gain regions 160, 170, and 180 may be the gain waveguide type. However, when it is taken into account that a predetermined difference is provided between the effective refractive index of the gain portions 162 and 172 and the effective refractive index of the portion excluding the gain regions 160 and 170, at least the gain portions 162 and 172 having curvatures desirably have structure of the index-guiding type.

The light-emitting device 100 according to this embodiment can be applied to light sources for a projector, a display, a lighting apparatus, a measuring apparatus, or the like.

The light-emitting device 100 according to this embodiment has, for example, characteristics explained below.

In the light-emitting device 100, the first gain region 160 includes the first gain portion 162 having the first curvature and the second gain region 170 includes the second gain portion 172 having the second curvature. Therefore, it is possible to make the distance D between the second end face 191 of the first gain region 160 and the fourth end face 193 of the second gain region 170 (the distance D between the light emitting areas) large without increasing the incident angle β of the lights generated in the gain regions 160 and 170 on the second surface 132. Consequently, it is possible to suppress a radiation pattern of emitted light from being distorted. For example, when the light-emitting device 100 is used for a light source of a projector, it is possible to uniformly illuminate a light valve.

Further, with the light-emitting device 100, compared with an example in which a gain region is liner from a first surface to a second surface is used, the total length of the gain regions does not have to be increased in order to make the distance D large. Therefore, it is unnecessary to inject a very large current and it is possible to suppress power consumption. Further, since the total length of the gain regions does not have to be increased, it is possible to realize a reduction in size of the entire device. Therefore, resources are not wasted and it is possible to suppress manufacturing costs.

As explained above, in the light-emitting device 100, a radiation pattern is satisfactory and it is possible to make the distance D large while realizing a reduction in the size of the light-emitting device 100. More specifically, in the light-emitting device 100, it is possible to set the distance D between the light emitting areas to be equal to or larger than 0.262 mm and equal to or smaller than 1.909 mm, set the angle β to be equal to or smaller than 5 degrees (including 0 degree), and set the total length of the gain regions 160 and 170 to be equal to or larger than 1.5 mm and equal to or smaller than 3 mm.

With the light-emitting device 100, the first gain region 160 can be connected to the first surface 130 while tilting at the first angle α1 with respect to the perpendicular P and the second gain region 170 can be connected to the first surface 130 while tilting at the second angle α2 with respect to the perpendicular P. The first and second angles α1 and α2 can be equal to or larger than the critical angle and can be the same size. Therefore, the first surface 130 can totally reflect lights generated in the gain regions 160 and 170. Therefore, in the light-emitting device 100, it is possible to suppress an optical loss at the first surface 130 and efficiently reflect the light. Further, since a process for forming a reflection film on the first surface 130 is unnecessary, it is possible to reduce manufacturing costs and materials and resources necessary for manufacturing.

With the light-emitting device 100, the third gain region 180 can be an optical resonator. Therefore, light generated in the third gain region 180 can couple with the lights guided in the first gain regions 160 and the second gain region 170 while resonating in the third gain region 180 and emitted from the second end face 191 and the fourth end face 193. Accordingly, although a distance between the two light emitting areas is the same as an emission surface space set when the third gain region 180 is not formed, it is possible to increase the output of the light-emitting device 100 compared with the output obtained when the third gain region 180 is not formed.

With the light-emitting device 100, the first surface 130 can be a surface formed by cleavage. Therefore, for example, compared with the case in which the first surface 130 is formed by the photolithography technique and the etching technique, it is possible to accurately form the first surface 130 and reduce light scattering at an end face. Therefore, in the light-emitting device 100, it is possible to suppress an optical loss at the first surface 130 and efficiently reflect light.

### 2. Manufacturing Method for the Light-Emitting Device

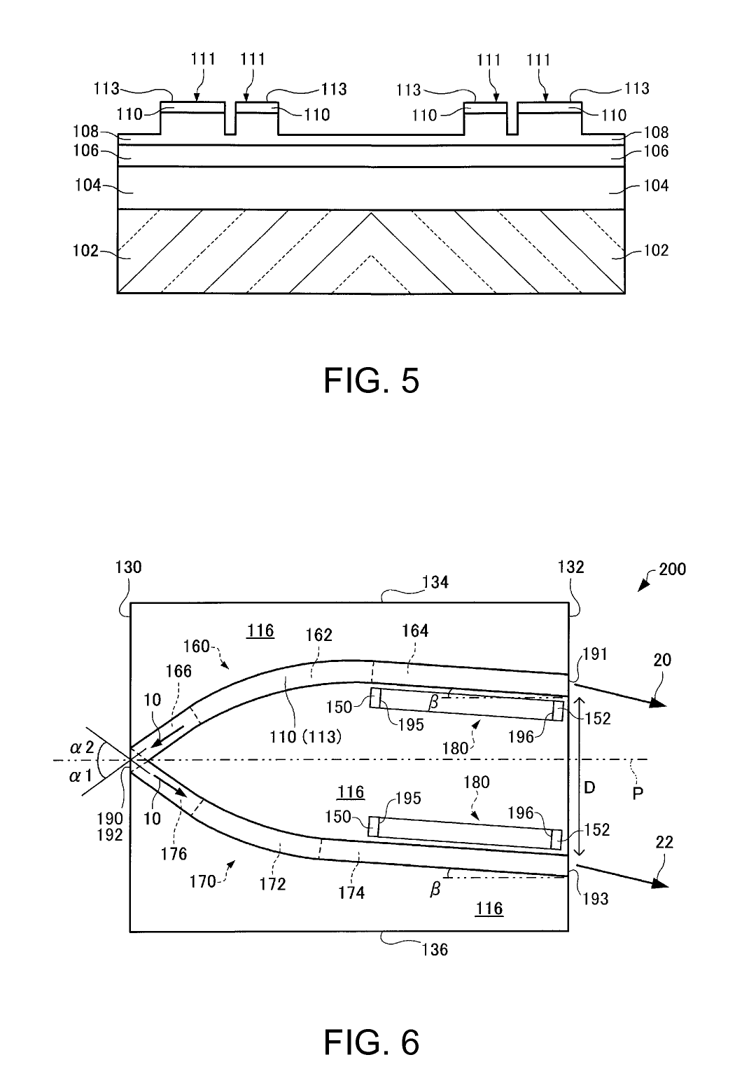

A manufacturing method for the light-emitting device according to this embodiment is explained with reference to the drawings. FIG. 4 is a sectional view schematically showing a manufacturing process for the light-emitting device 100 according to this embodiment. FIG. 4 corresponds to FIG. 2. FIG. 5 is a sectional view schematically showing the manufacturing process for the light-emitting device 100 according to this embodiment. FIG. 5 corresponds to FIG. 2.

As shown in FIG. 4, the first cladding layer 104, the active layer 106, the second cladding layer 108, and the contact layer 110 are epitaxially grown on the substrate 102 in this order. As a method of epitaxial growth, for example, an MOCVD (Metal Organic Chemical Vapor Deposition) method and an MBE (Molecular Beam Epitaxy) method can be used.

As shown in FIG. 5, the contact layer 110 and the second cladding layer 108 are patterned. The patterning is performed using, for example, the photolithography technique and the etching technique. The columnar sections 111 can be formed according to this step.

Subsequently, as shown in FIG. 3, the first groove 150 and the second groove 152 are formed by patterning the contact layer 110, the second cladding layer 108, the active layer 106, the first cladding layer 104, and the substrate 102. The patterning is performed using, for example, the photolithography technique and the etching technique. The bottom surfaces of the grooves 150 and 152 are desirably provided below the position of the lower surface of the active layer 106. In the light-emitting device 100 according to this embodiment, the positions of the bottom surfaces of the grooves 150 and 152 are below the position of the upper surface of the substrate 102.

Subsequently, as shown in FIG. 2, the insulating layer 116 is formed to cover the side surfaces of the columnar sections 111. Specifically, first, an insulating member (not shown) is formed above the second cladding layer 108 (including on the contact layer 110) by, for example, a CVD (Chemical Vapor Deposition) method or a coating method. The upper surface 113 of the contact layer 110 is exposed using, for example, the etching technique. The insulating layer 116 can be formed according to the step explained above. In this step, the first groove 150 and the second groove 152 can be filled with an insulating layer. However, it is also possible that the grooves 150 and 152 are not be filled with the insulating layer by, for example, covering the regions of the grooves 150 and 152 with a resist film (not shown) or the like.

The second electrode 114 is formed on the contact layer 110 and the insulating layer 116. The second electrode 114 can be formed in a desired shape by covering a predetermined region, the region the second electrode is not formed at the end, with the resist film (not shown) using the photolithography technique and, then, performing a vacuum evaporation method and a lift-off method. It is desirable that regions larger than the grooves 150 and 152 are covered with the resist film or the like to prevent an electrode material from entering the grooves to cause short-circuit.

The first electrode 112 is formed on the lower surface of the substrate 102. The first electrode 112 is formed by, for example, the vacuum evaporation method. The order of the formation of the first electrode 112 and the second electrode 114 is not specifically limited.

With the process explained above, it is possible to manufacture the light-emitting device 100 according to this embodiment.

With the manufacturing method for the light-emitting device 100, it is possible to obtain the light-emitting device 100 in which a radiation pattern is satisfactory and it is possible to make distances between plural light emitting areas large while realizing a reduction in the size of the light-emitting device 100.

### 3. Light-Emitting Devices According to Modifications

Light-emitting devices according to modifications of this embodiment are explained with reference to the accompanying drawings. In the following explanation, in the light-emitting devices according to the modifications of the embodiment, members having the same functions as that of the members of the light-emitting device 100 are denoted by the same reference numerals and signs and detailed explanation of the members is omitted.

### 3.1. Light-Emitting Device According to a First Modification

First, a light-emitting device according to a first modification of this embodiment is explained with reference to the accompanying drawings. FIG. 6 is a plan view schematically showing a light-emitting device 200 according to the first modification of this embodiment. In FIG. 6, for convenience of illustration, the second electrode 114 is not shown.

In the example of the light-emitting device 100, as shown in FIG. 1, the gain portions 162 and 172 having the curvatures are connected to the first surface 130. On the other hand, in the light-emitting device 200, as shown in FIG. 6, linear gain portions 166 and 176 are connected to the first surface 130.

Specifically, the first gain region 160 includes a fifth gain portion (a fifth portion) 166 linearly provided from the first surface 130 to the first gain portion 162. In other words, the fifth gain portion 166 forms the first end face 190 of the first gain region 160. The fifth gain portion 166 tilts at the first angle α1 to one side (e.g., the third surface 134 side) with respect to the perpendicular P. The fifth gain portion 166 is smoothly connected to the arc-shaped first gain portion 162. For example, the fifth gain portion 166 is provided to be parallel to a tangent at a point on the boundary between the first gain portion 162 and the fifth gain portion 166.

The second gain region 170 includes a sixth gain portion (a sixth portion) 176 linearly provided from the first surface 130 to the second gain portion 172. In other words, the sixth gain portion 176 forms the third end face 192 of the second gain region 170. The sixth gain portion 176 tilts at the second angle α2 to the other side (e.g., the fourth surface 136 side) with respect to the perpendicular P. The sixth gain portion 176 is smoothly connected to the arc-shaped second gain portion 172. For example, the sixth gain portion 176 is provided to be parallel to a tangent at a point on the boundary between the second gain portion 172 and the sixth gain portion 176. The gain portions 166 and 176 may be arranged symmetrically with respect to the perpendicular P.

With the light-emitting device 200, as explained above, the linear gain portions 166 and 176 form the end faces 190 and 192 provided on the first surface 130. Therefore, in the light-emitting device 200, compared with the example of the light-emitting device 100, it is possible to more surely make light generated in the first gain region 160 and reflected on the first surface 130 enter the second gain region 170 and more surely make light generated in the second gain region 170 and reflected on the first surface 130 enter the first gain region 160.

### 3.2. Light-Emitting Device According to a Second Modification

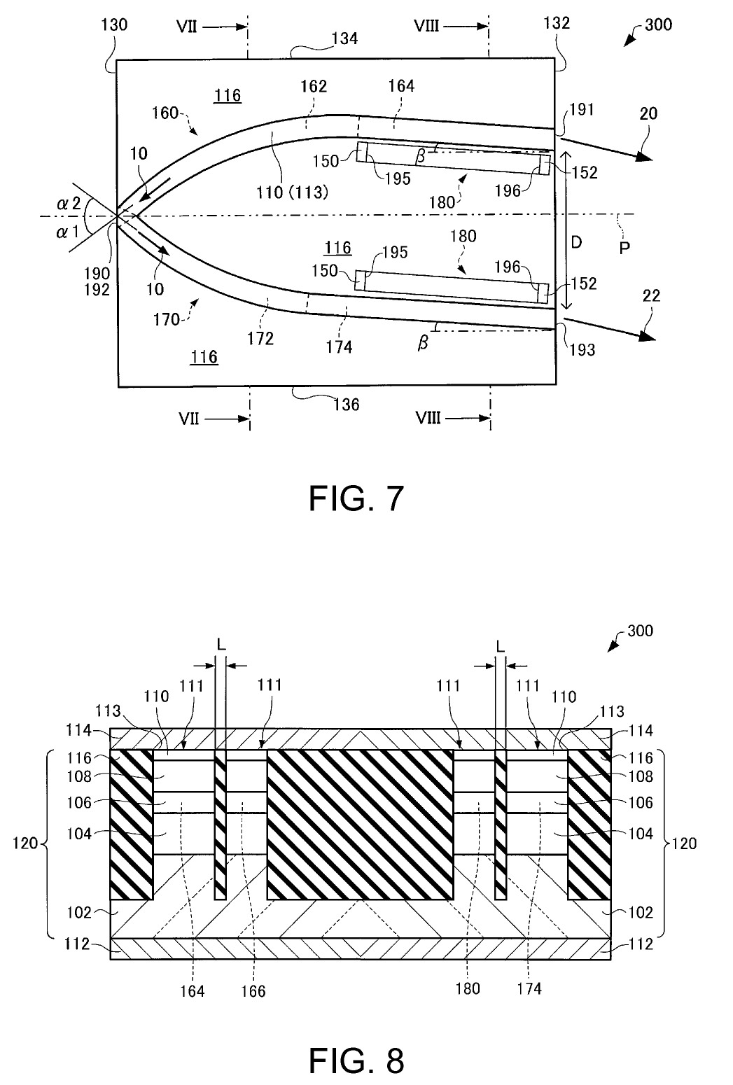

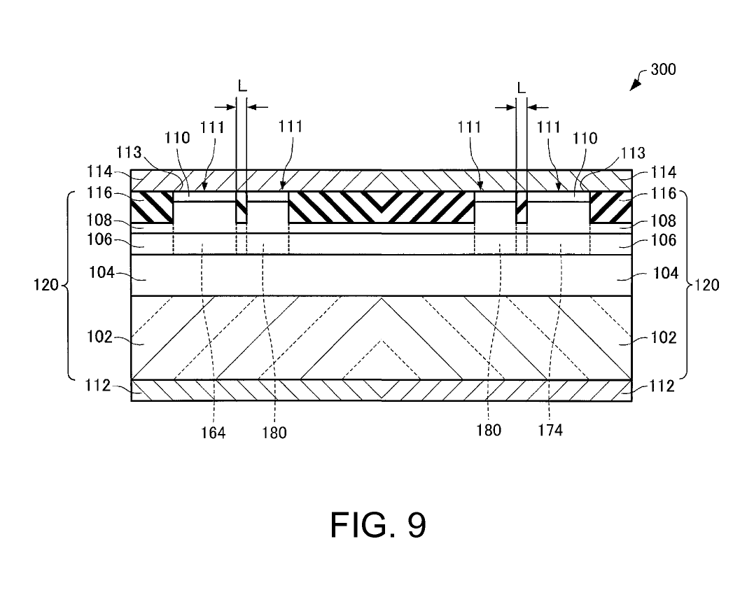

A light-emitting device according to a second modification of this embodiment is explained with reference to the accompanying drawings. FIG. 7 is a plan view schematically showing a light-emitting device 300 according to the second modification of this embodiment. FIG. 8 is a sectional view schematically showing the light-emitting device 300 according to the second modification of this embodiment. FIG. 8 is a sectional view taken along line VII-VII in FIG. 7. FIG. 9 is a sectional view schematically showing the light-emitting device 300 according to the second modification of this embodiment. FIG. 9 is a sectional view taken along line VIII-VIII in FIG. 7. In FIG. 7, for convenience of illustration, the second electrode 114 is not shown.

In the example of the light-emitting device 100, as shown in FIG. 2, the columnar sections 111 are composed of the contact layer 110 and part of the second cladding layer 108. On the other hand, in the light-emitting device 300, as shown in FIG. 8, the columnar sections 111 forming the plane shape of the gain portions 162 and 172 are composed of the contact layer 110, the second cladding layer 108, the active layer 106, the first cladding layer 104, and part of the substrate 102.

Although not shown in the figure, the columnar sections 111 forming the plane shape of the gain portions 162 and 172 may be composed of, for example, the contact layer 110, the second cladding layer 108, the active layer 106, and the first cladding layer 104.

As the insulating layer 116, as explained above, a dielectric layer such as an SiN layer, an SiO₂ layer, an SiON layer, or an Al₂O₂ layer, a thermoset or an ultraviolet curable resin layer such as a polyimide layer can be used. The insulating layer 116 may be formed by stacking these layers. When it is taken into account that a predetermined difference is provided between the effective refractive index of the gain portions 162 and 172 and the effective refractive index of the portion excluding the gain regions 160 and 170 in FIG. 8, it is desirable to use a insulating layer having a large refractive index difference from the columnar sections 111. For example, it is also possible that the insulating layer 116 is formed by, first, depositing the dielectric layer using a CVD method or a sputtering method and, then, forming a polyimide layer using a coating method. Consequently, compared with depositing the dielectric layer thicker to form the insulating layer 116, it is possible to form the insulating layer 116 easily (in a short time).

With the light-emitting device 300, compared with the light-emitting device 100, it is possible to increase a difference between the effective refractive index of the gain portions 162 and 172 and the effective refractive index of the portion excluding the gain regions 160 and 170 (to a predetermined value) and more efficiently guide light in the gain portions 162 and 172.

As shown in FIG. 9, the columnar sections 111 forming the plane shape of the linear gain portions 164 and 174 are desirably formed by the contact layer 110 and part of the second cladding layer 108. When the columnar sections 111 forming the plane shape of the gain portions 164 and 174 are formed by the contact layer 110, the second cladding layer 108, the active layer 106, the first cladding layer 104, and part of the substrate 102 as shown in FIG. 8, a high-order mode (a mode having a larger wave numbers in a direction crossing the gain regions (a direction perpendicular to a propagation direction in a horizontal plane)) may propagate in the gain regions 160 and 170 and a radiation pattern may be deteriorated.

It is also possible that the insulating layer 116 is not provided. In this case, surrounding air can function as the insulating layer 116. When the insulating layer 116 is not provided, a difference between the effective refractive index of the gain portions 162 and 172 and the effective refractive index of the portion excluding the gain regions 160 and 170 in FIG. 8 can be increased (the refractive index of the air is about 1.0 and the refractive index of SiN is about 2.1). However, because of the large difference, a difference between the effective refractive index of the portion excluding the gain regions 160 and 170 in FIG. 8 and the effective refractive index in the portion excluding the gain regions 160 and 170 in FIG. 9 may also be large. For example, when light is made enter the first gain portion 162 from the third gain portion 164, a reflectance at the interface may also be large. Therefore, an optical loss can be large. Therefore, it is desirable to provide the insulating layer 116 as described above.

### 3.3. Light-Emitting Device According to a Third Modification

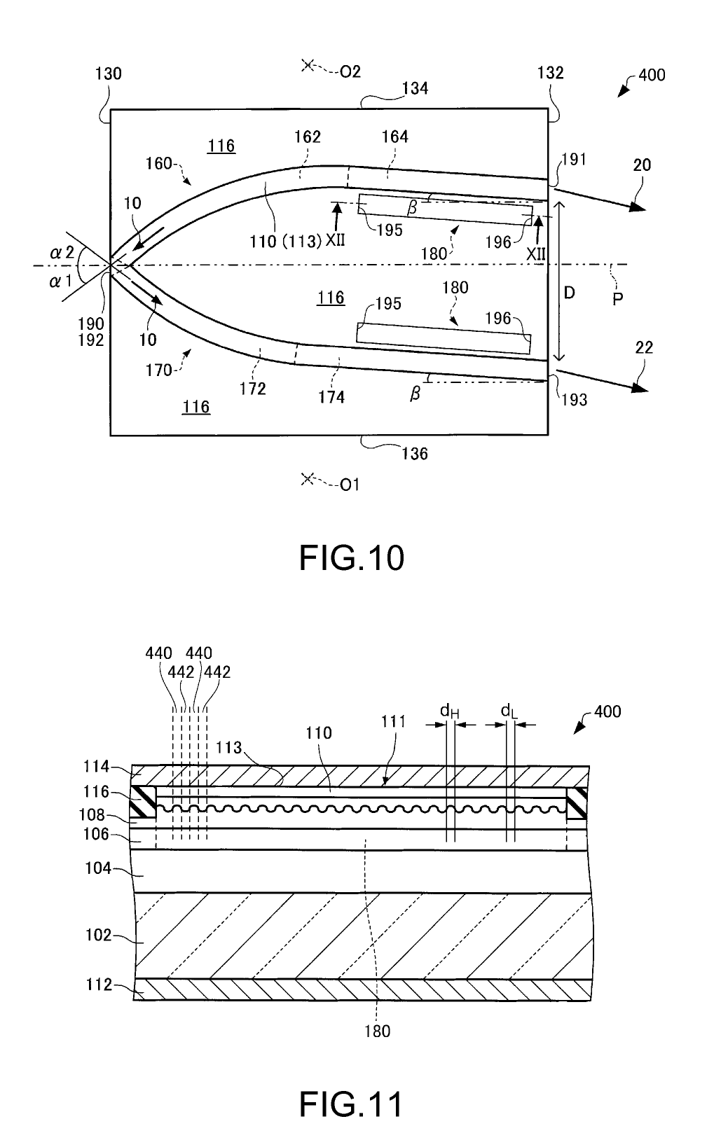

A light-emitting device according to a third modification of this embodiment is explained with reference to the accompanying drawings. FIG. 10 is a plan view schematically showing a light-emitting device 400 according to the third modification of this embodiment. FIG. 11 is a sectional view schematically showing the light-emitting device 400 according to the third modification of this embodiment. FIG. 11 is a sectional view taken along line XII-XII in FIG. 10. In FIG. 10, for convenience of illustration, the second electrode 114 is not shown.

In the example of the light-emitting device 100, the optical resonator of the third gain region 180 is an optical resonator of an edge reflection type in which, as shown in FIG. 1, the fifth end face 195 and the sixth end face 196 are formed by forming the grooves 150 and 152 and the light generated in the third gain region 180 is reflected according to a difference between the effective refractive index of the third gain region 180 and the effective refractive index of the grooves. On the other hand, an optical resonator of the third gain region 180 of the light-emitting device 400 according to the third modification of this embodiment can be an optical resonator of a distributed feedback type (also referred to as DFB type) as shown in FIG. 10.

More specifically, in the light-emitting device 400 according to the third modification of this embodiment, as shown in FIG. 11, high-refractive index regions 440 and the low-refractive index regions 442 are periodically formed in the extending direction of the third gain region 180 (the waveguide direction) at a region provided between the fifth end face 195 and the sixth end face 196 in at least one of the layers of the first cladding layer 104, the active layer 106, and the second cladding layer 108. Consequently, a light generated in the third gain region 180 and propagating in one direction of the waveguide in the third gain region 180 can be diffracted toward a 180 degree direction (an opposite direction of the waveguide direction) on interfaces between the high-refractive index regions 440 and the low-refractive index regions 442. The light diffracted in the opposite direction of the waveguide direction can be diffracted toward the original waveguide direction again. In other words, the third gain region 180 can be an optical resonator of the distributed feedback type in which light is repeatedly reflected by diffraction on the interfaces between the high-refractive index regions 440 and the low-refractive index regions 442.

In order to form such an optical resonator of the distributed feedback type, lengths d_{H} and d_{L} in the extending directions of the high-refractive index regions 440 and the low-refractive index regions 442 need to be appropriately designed. Specifically, when the center wavelength of light generated in the active layer 106 is represented as λ, the effective refractive index of the vertical cross section of the laminated body 120 of portions forming the high-refractive index regions 440 is represented as n_{H}, and the effective refractive index of the vertical cross section of the laminated body 120 of portions forming the low-refractive index regions 442 is represented as n_{L}, the lengths d_{H} and d_{L} can be set to, for example, about d_{H}=(2m_{H}+1)λ/(4n_{H}) and d_{L}=(2m_{L}+1)λ/(4n_{L}), where m_{H} and m_{L} are integers equal to or larger than 0. Consequently, the light can resonate at most at two wavelengths λ_{R1} and λ_{R2} near λ. For example, in the case of m_{H}=m_{L}=0, the light can resonate at wavelengths λ_{R1} and λ_{R2} that satisfy 2n_{L}λ/(n_{H}+n_{L})<λ_{R1} and λ_{R2}<2n_{H}λ/(n_{H}+n_{L}). Specific resonant wavelengths λ_{R1} and λ_{R2} can be analyzed by performing a numerical analysis of a transfer matrix method, an FDTD (Finite Difference Time Domain) method, a plane wave expansion method, or the like. The lengths d_{H} and d_{L} in the extending direction of the high-refractive index regions 440 and the low-refractive index regions 442 can be appropriately adjusted according to the numerical analysis in a range in which the resonant wavelengths λ_{R1} and λ_{R2} are within a wavelength band of the light generated in the active layer 106 (usually, about λ±several tens nanometers depending on a light-emitting material).

The high-refractive index regions 440 and the low-refractive index regions 442 can be formed by, for example, a method explained below. First, the first cladding layer 104, the active layer 106, and a layer having a refractive index higher than the refractive index of the second cladding layer 108 to be grown later is grown by the MOCVD method or the like. Subsequently, the layer is patterned by an interference exposure technique, an immersion exposure technique, an EB lithography technique, or a nano imprint lithography technique and the etching technique to expose the active layer 106 in portions other than portions to be formed as the high-refractive index regions 440 later. Then, the second cladding layer 108 and the contact layer 110 are grown by the MOCVD method or the like. Consequently, in the laminated body 120, the effective refractive index in the vertical cross section of the portions where the refractive index higher than the refractive index of the second cladding layer 108 is left is higher than that of the portions where the refractive index higher than the refractive index of the second cladding layer 108 is etched. The following steps are the same steps as that of the manufacturing method of the light-emitting device 100. Consequently, it is possible to form the high-refractive index regions 440 and the low-refractive index regions 442.

A method of forming the high-refractive index regions 440 and the low-refractive index regions 442 is not limited to the method explained above. For example, after the first cladding layer 104, the active layer 106, and the second cladding layer 108 are grown, the high-refractive index regions 440 and the low-refractive index regions 442 may be formed by patterning the second cladding layer 108. The method can be appropriately changed according to the materials of the quantum wells and the cladding layers, the lengths d_{H} and d_{L} of the high-refractive index regions 440 and the low-refractive index regions 442, the refractive indexes n_{H} and n_{L} of the high-refractive index regions 440 and the low-refractive index regions 442, or the like.

In the light-emitting device 100, the third gain region 180 is the optical resonator of an edge reflection type. Therefore, the light reflected on the fifth end face 195 and the sixth end face 196 couples with the light guided in the first gain region 160 or the second gain region 170 and is emitted from the second end face 191 or the fourth end face 193. However, the light transmitted through the fifth end face 195 and the sixth end face 196 is lost. On the other hand, in the light-emitting device 400, the third gain region 180 is the optical resonator of the distributed feedback type. Therefore, according to the multiple reflections, a large amount of the light couples with the light guided in the first gain region 160 or the second gain region 170 before it reaches the end faces 195 and 196 of the third gain region 180 and is emitted from the second end face 191 or the fourth end face 193. In other words, it is possible to reduce a transmission loss at the end faces. Therefore, compared with the light-emitting device 100, it is possible to make the distance between the light emitting areas large while realizing an increase in the output of the light-emitting device 400.

### 3.4. Light-Emitting Device According to a Fourth Modification

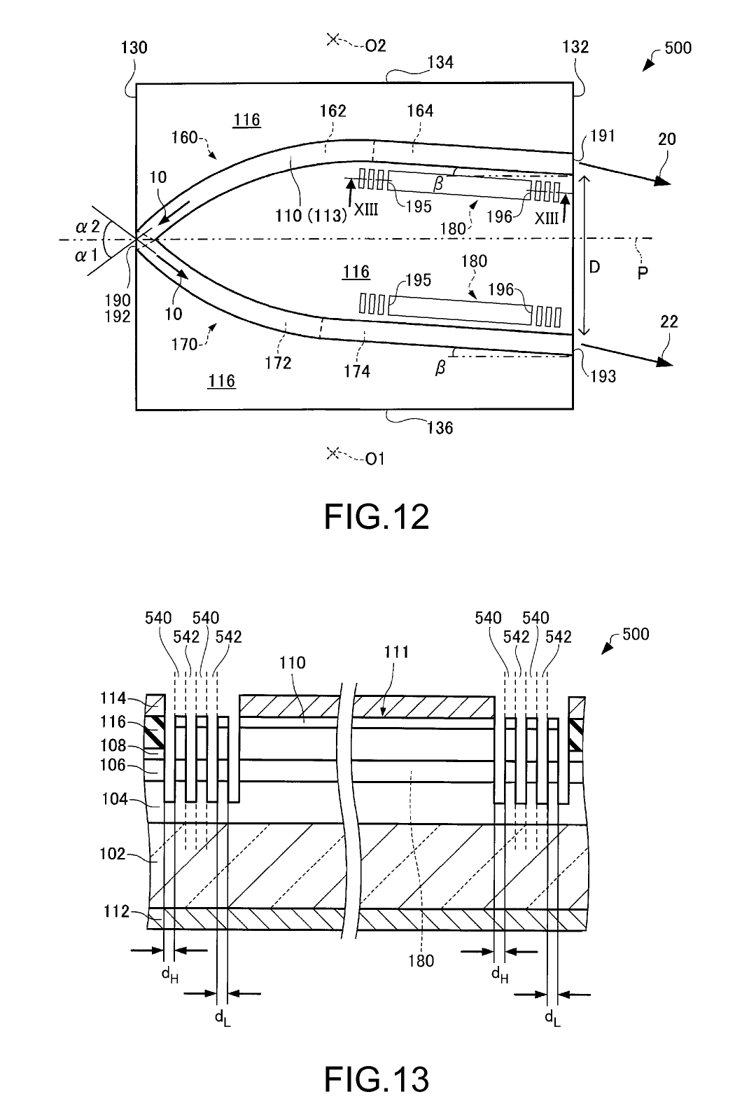

A light-emitting device according to a fourth modification of this embodiment is explained with reference to the accompanying drawings. FIG. 12 is a plan view schematically showing a light-emitting device 500 according to the fourth modification of this embodiment. FIG. 13 is a sectional view schematically showing the light-emitting device 500 according to the fourth modification of this embodiment. FIG. 13 is a sectional view taken along line XIII-XIII in FIG. 12. In FIG. 12, for convenience of illustration, the second electrode 114 is not shown.

In the example of the light-emitting device 100, the optical resonator of the third gain region 180 is an optical resonator of an edge reflection type in which, as shown in FIG. 1, the fifth end face 195 and the sixth end face 196 are formed by forming the grooves 150 and 152 and the light generated in the third gain region 180 is reflected according to a difference between the effective refractive index of the third gain region 180 and the effective refractive index of the grooves. On the other hand, an optical resonator of the third gain region 180 of the light-emitting device 500 according to the fourth modification of this embodiment can be an optical resonator in which distributed Bragg reflectors (also referred to as DBRs) are formed on the outer sides of the fifth end face 195 and the sixth end face 196 shown in FIG. 12.

More specifically, in the light-emitting device 500 according to the fourth modification of this embodiment, as shown in FIG. 13, high-refractive index regions 540 and the low-refractive index regions 542 are periodically formed toward the extending direction of the third gain region 180 (the waveguide direction) in at least one of the layers of the first cladding layer 104, the active layer 106, and the second cladding layer 108 on the outer sides of the fifth end face 195 and the sixth end face 196. Consequently, light generated in the third gain region 180 and propagating in the third gain region 180 toward the fifth end face 195 can be diffracted toward a 180 degree direction (an opposite direction of the waveguide direction) on interfaces between the high-refractive index regions 540 and the low-refractive index regions 542 on the outer side of the fifth end face 195. A part of the light diffracted in the opposite direction of the waveguide direction can propagate in the third gain region 180 toward the sixth end face 196. Another part of the light diffracted in the opposite direction of the waveguide direction can be diffracted toward the original waveguide direction again. In this way, substantially all lights propagating in the third gain region 180 toward the fifth end face 195 are finally reflected in the direction of the sixth end face 196 while repeating the multiple reflections by the diffraction on the interfaces between the high-refractive index regions 540 and the low-refractive index regions 542. In other words, the high-refractive index regions 540 and the low-refractive index regions 542 can form DBRs. Similarly, substantially all lights generated in the third gain region 180 and propagating in the third gain region 180 toward the sixth end face 196 are finally reflected in the direction of the fifth end face 195 while repeating the multiple reflections by the diffraction on the interfaces between the high-refractive index regions 540 and the low-refractive index regions 542. Therefore, the third gain region 180 can be considered an optical resonator using distributed Bragg reflectors in which light is repeatedly reflected between the DBRs formed on the outer side of the fifth end face 195 and the DBRs formed on the outer side of the sixth end face 196.

In order to form such an optical resonator using the distributed Bragg reflectors, lengths d_{H} and d_{L} in the extending directions of the high-refractive index regions 540 and the low-refractive index regions 542 need to be appropriately designed. Specifically, when the center wavelength of light generated in the active layer 106 is represented as λ, the effective refractive index of the vertical cross section of the laminated body 120 of portions forming the high-refractive index regions 540 is represented as n_{H}, and the effective refractive index of the vertical cross section of the laminated body 120 of portions forming the low-refractive index regions 542 is represented as n_{L}, the length d_{H} and d_{L} can be set to, for example, about d_{H}=(2m_{H}+1)λ/(4n_{H}) and d_{L}=(2m_{L}+1)λ/(4n_{L}), where m_{H} and m_{L} are integers equal to or larger than 0. Consequently, when the wavelength width of light generated in the active layer 106 is represented as Δλ and the length of the third gain region 180 is represented as L₃, the light can resonate at a large number of resonant wavelengths λ_{Rm}=2nL₃/m (n is the effective refractive index of the third gain region 180 and m is a positive integer) that satisfy λ−Δλ/2≦λ_{Rm}≦λ+Δλ/2. Δλ is about several tens nanometers depending on a light-emitting material.

The high-refractive index regions 540 and the low-refractive index regions 542 can be formed by, for example, the same method as that of forming the grooves 150 and 152 in the light-emitting device 100. Specifically, like the grooves 150 and 152, the low-refractive index regions 542 can be formed by patterning regions to be the low-refractive index regions 542 with the photolithography technique and the etching technique. When the low-refractive index regions 542 are periodically formed, regions periodically left without being etched are the high-refractive index regions 540. Like the grooves 150 and 152, when the insulating layer 116 is formed, the low-refractive index regions 542 can be filled with the insulating layer 116 or can not be filled with the insulating layer 116.

A method of forming the high-refractive index regions 540 and the low-refractive index regions 542 is not limited to the method explained above. For example, as in the third modification, the interference exposure technique, the liquid immersion exposure technique, the EB lithography technique, or the nano-imprint lithography technique can also be applied to the patterning depending on the length d_{H} and d_{L} of the high-refractive index regions 540 and the low-refractive index regions 542. After grooves are formed in the same manner as the grooves 150 and 152, the high-refractive index regions 540 and the low-refractive index regions 542 may be formed by alternately stacking a high-refractive index material and a low-refractive index material from side surfaces of the grooves with the CVD method, the sputtering method, an oblique evaporation method, or the like. The method can be appropriately changed according to the materials of the quantum wells and the cladding layers, the lengths d_{H} and d_{L} of the high-refractive index regions 540 and the low-refractive index regions 542, the refractive indexes n_{H} and n_{L} of the high-refractive index regions 540 and the low-refractive index regions 542, or the like.

In the light-emitting device 100, the third gain region 180 is the optical resonator of an edge reflection type. Therefore, the light reflected on the fifth end face 195 and the sixth end face 196 couples with the light guided in the first gain region 160 or the second gain region 170 and is emitted from the second end face 191 or the fourth end face 193. However, the light transmitted through the fifth end face 195 and the sixth end face 196 is lost. On the other hand, in the light-emitting device 500, substantially all lights can be finally reflected while repeating the multiple reflections by the diffraction on the interfaces between the high-refractive index regions 540 and the low-refractive index regions 542. Therefore, it is possible to reduce a transmission loss. In other words, in the light-emitting device 500, compared with the light-emitting device 100, it is possible to make the light emitting area distance large while realizing an increase in the output of the light-emitting device 500.

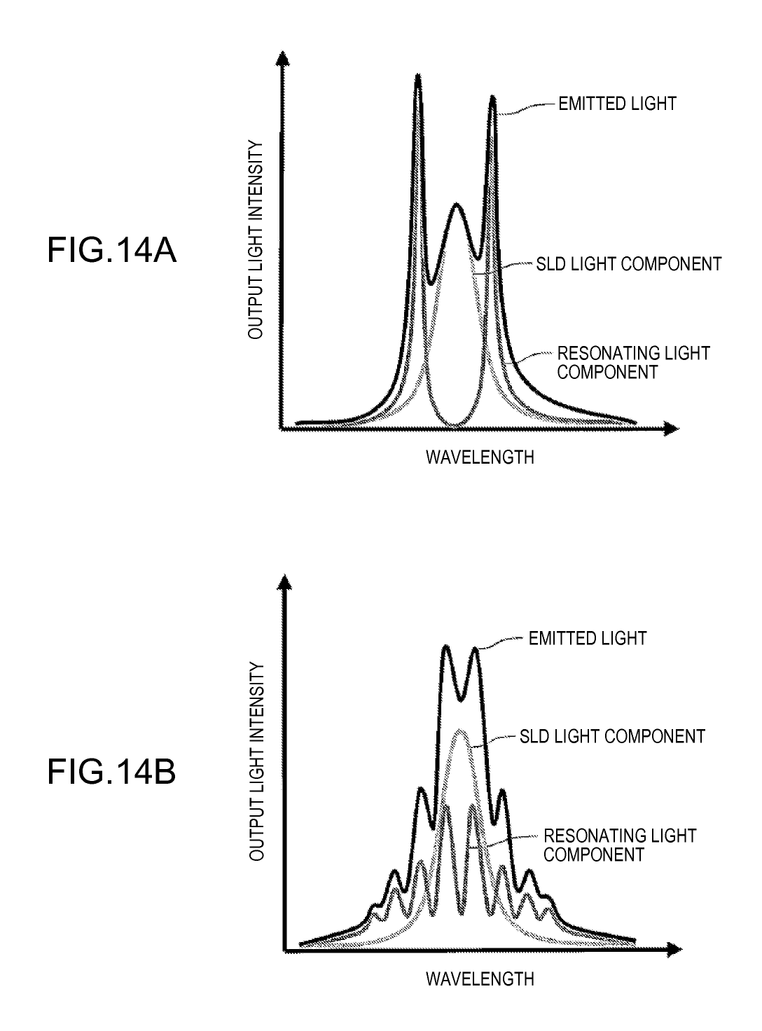

FIGS. 14A and 14B are graphs schematically showing spectrum shapes of lights output from the light-emitting devices. The vertical axis represents intensity of output light and the horizontal axis represents wavelength.

In the light-emitting device 400, the third gain region 180 is the optical resonator of the distributed feedback type. Therefore, light resonates at most only at the two wavelengths λ_{R1} and λ_{R2}. When the resonant light is combined with light generated in the SLD region, a spectrum shape of the lights 20 and 22 emitted from the second end face 191 and the fourth end face 193 of the light-emitting device 400 is considered to be a shape schematically shown in FIG. 14A. On the other hand, in the light-emitting device 500, the third gain region 180 is the optical resonator using distributed Bragg reflector. Therefore, light can resonate at a large number of resonant wavelengths λ_{Rm}=2nL₃/m (n is the effective refractive index of the third gain region 180 and m is a positive integer) that satisfy λ−Δλ/2≦λ_{Rm}≦λ+Δλ/2. Therefore, when the resonant light is combined with light generated in the SLD region, a spectrum shape of the lights 20 and 22 emitted from the second end face 191 and the fourth end face 193 of the light-emitting device 500 is considered to be a shape schematically shown in FIG. 14B. Therefore, compared with the case of the light-emitting device 400 in which light intensity of only specific resonant wavelengths is high, in the case of the light-emitting device 500, light intensity of a large number of resonant wavelengths is high and incoherent properties can be improved. In other words, in the light-emitting device 500, compared with the light-emitting device 400, it is possible to make the distance between light emitting areas large while reducing speckle noise.

### 3.5. Light-Emitting Device According to a Fifth Modification

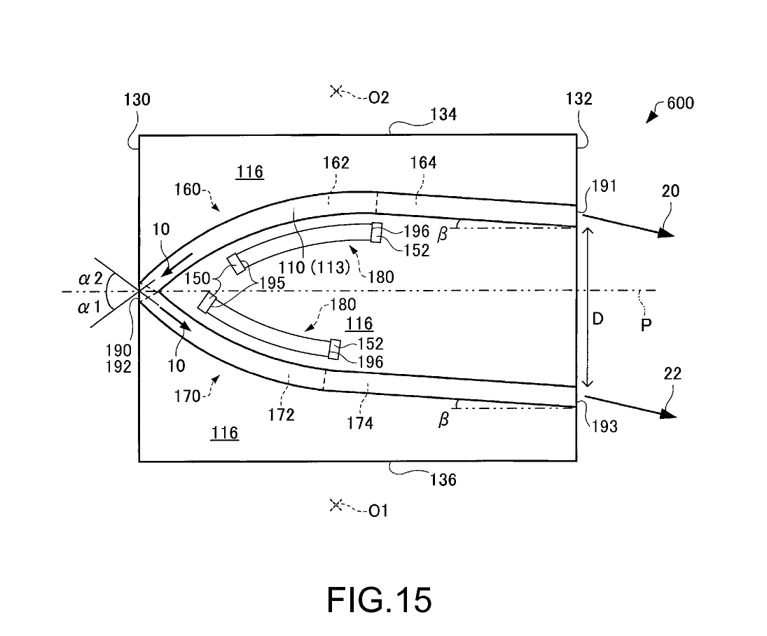

A light-emitting device according to a fifth modification of this embodiment is explained with reference to the accompanying drawings. FIG. 15 is a plan view schematically showing a light-emitting device 600 according to the fifth modification of this embodiment.

In the example of the light-emitting device 100, as shown in FIG. 1, the third gain region 180 is provided along the third gain portion 164 and the fourth gain portion 174, which are the linear gain portions of the first gain region 160 and the second gain region 170. More specifically, the third gain region 180 is linearly provided in parallel along the third gain portion 164 or the forth gain portion 174. On the other hand, in the light-emitting device 600 according to the fifth modification of this embodiment, as shown in FIG. 15, the third gain region 180 is provided along the first gain portion 162 and the second gain portion 172, which are gain portions having curvatures. More specifically, the third gain region 180 in the light-emitting device 600 has a curvature. The third gain region 180 is provided such that a distance between a center line drawn along the tangential direction of the third gain region 180 and center line drawn along the tangential direction of the first gain portion 162 or the second gain portion 172 is fixed. A distance L between the third gain region 180 and the first or second gain portion 162 or 172 is, for example, 100 nm to about a double of the width of the gain region (several micrometers to several tens micrometers) depending on the effective refractive indexes of the gain region and the portion excluding the gain region.

For example, when the first gain portion 162 and the second gain portion 172 have an arc shape, the shape of the third gain region 180 can also be an arc shape concentric with the first gain portion 162 or the second gain portion 172. More specifically, when the first gain portion 162 has an arc shape around a point O1 and the second gain portion 172 has an arc shape around a point O2, the third gain region 180 can have an arc shape having a different curvature radius around the point O1 or the point O2.

In the light-emitting device 600, as in the light-emitting devices explained above, the fifth end face 195 and the sixth end face 196 can be formed perpendicularly to the extending direction of the third gain region 180. For example, when the third gain region 180 has an arc shape, the fifth end face 195 and the sixth end face 196 can be formed in parallel to the radial direction. Consequently, light generated in the third gain region 180 can be repeatedly reflected between the fifth end face 195 and the sixth end face 196. In other words, the third gain region 180 can form an optical resonator.

When such a third gain region 180 having the curvature is used, as in the light-emitting device 100, light generated in the third gain region 180 and resonating in the third gain region 180 can efficiently couple with lights guided in the first gain region 160 and the second guide region 170. As in the case of the light-emitting device 100, the coupled light can be emitted from the second end face 191 and the fourth end face 193. Although a distance between light emitting areas is the same as the distance formed when the third gain region 180 is not formed, it is possible to increase the output of the light-emitting device 600 compared with an output obtained when the third gain region 180 is not formed.

In the light-emitting device 600, the third gain region 180 has the curvature and is formed along the first gain portion 162 or the second gain portion 172. Therefore, when the length of the first gain portion 162 or the second gain portion 172 is large compared with the length of the third gain portion 164 or the fourth gain portion 174, the length of the third gain region 180 can be formed large more easily than in the light-emitting device 100. Therefore, in such a case, it is possible to easily increase the output of the light-emitting device 600 compared with the light-emitting device 100.

### 3.6. Light-Emitting Device According to a Sixth Modification

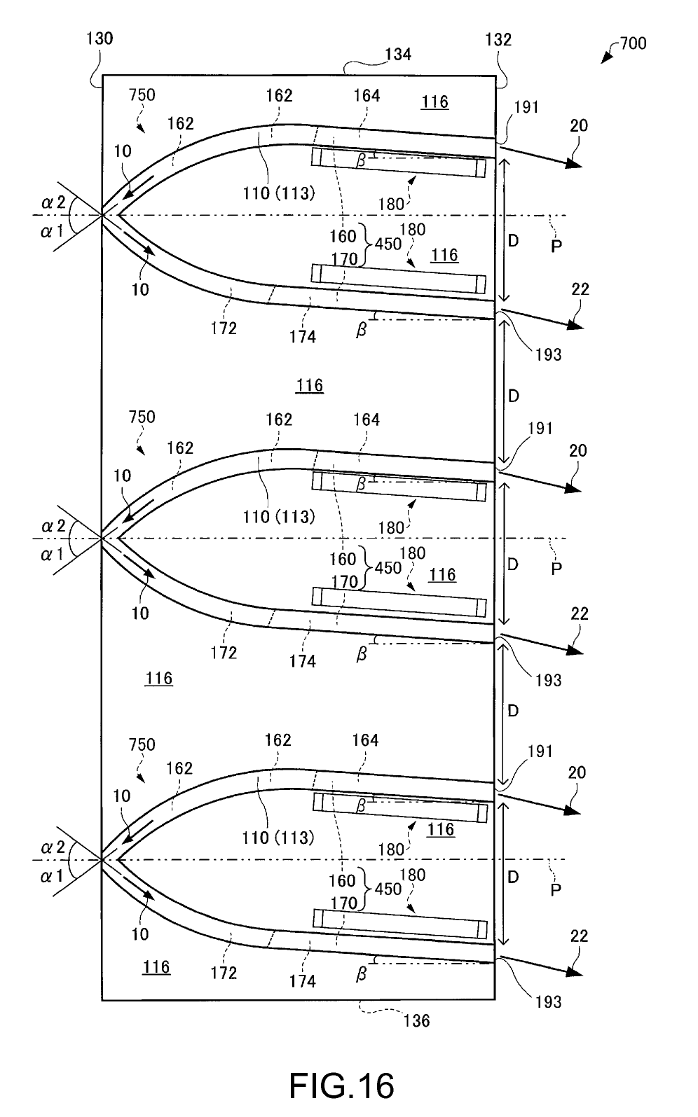

A light-emitting device according to a sixth modification of this embodiment is explained with reference to the accompanying drawings. FIG. 16 is a plan view schematically showing a light-emitting device 700 according to the sixth modification of this embodiment. In FIG. 16, for convenience of illustration, the second electrode 114 is omitted.

In the example of the light-emitting device 100, as shown in FIG. 1, one first gain region 160 and one second gain region 170 are provided, and the third gain region 180 is provided along the first gain region 160 or the second gain region 170. On the other hand, in the light-emitting device 700, as shown in FIG. 16, plural first gain regions 160 and plural gain regions 170 are provided. The third gain regions 180 are provided along the plural first gain regions 160 or the plural second gain regions 170.

The first gain region 160, the second gain region 170, and the third gain region 180 can form a gain region group 750. In the light-emitting device 700, plural gain region groups 750 are provided. In the example shown in the figure, three gain region groups 750 are provided. However, the number of gain region groups 750 is not specifically limited.

The plural gain region groups 750 are arranged in a direction orthogonal to the direction in which the perpendicular P extends. More specifically, the gain region groups 750 adjacent to each other are arranged such that a distance between the fourth end face 193 of one gain region group 750 and the second end face 191 of the other gain region group 750 is D (the distance between light emitting areas). Consequently, it is possible to easily make the lights 20 and 22 incident on a lens array explained later.

With the light-emitting device 700, compared with the example of the light-emitting device 100, it is possible to realize an increase in the output of the light-emitting device 700.

### 4. Projector

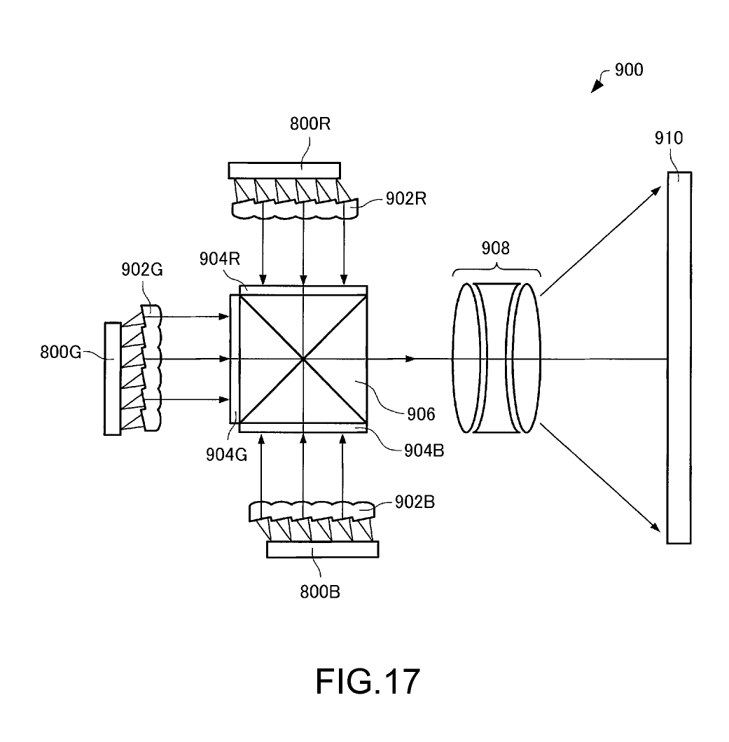

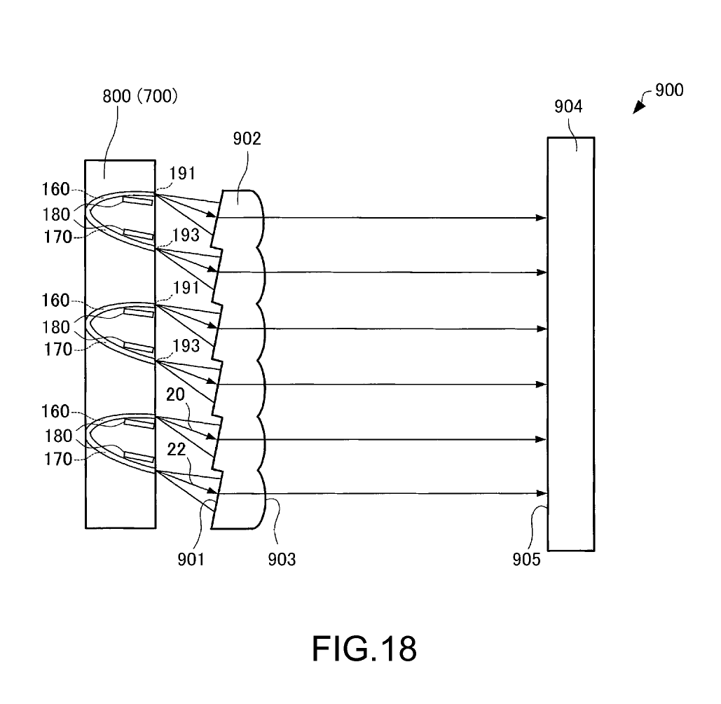

A projector according to this embodiment is explained with reference to the accompanying drawings. FIG. 17 is a diagram schematically showing a projector 900 according to this embodiment. FIG. 18 is a diagram schematically showing part of the projector 900 according to this embodiment. In FIG. 17, for convenience of illustration, a housing forming the projector 900 is not shown and a light source 800 is shown in a simplified form. In FIG. 18, for convenience of illustration, the light source 800, a lens array 902, and a liquid crystal light valve 904 are shown, and further, the light source 800 is shown in a simplified form.

The projector 900 includes, as shown in FIG. 17, a red light source 800R, a green light source 800G, and a blue light source 800B that emit red light, green light, and blue light. The light sources 800R, 800G, and 800B include the light-emitting device according to the invention. In an example explained below, the light sources 800R, 800G, and 800B including the light-emitting device 700 as the light-emitting device according to the invention are explained.

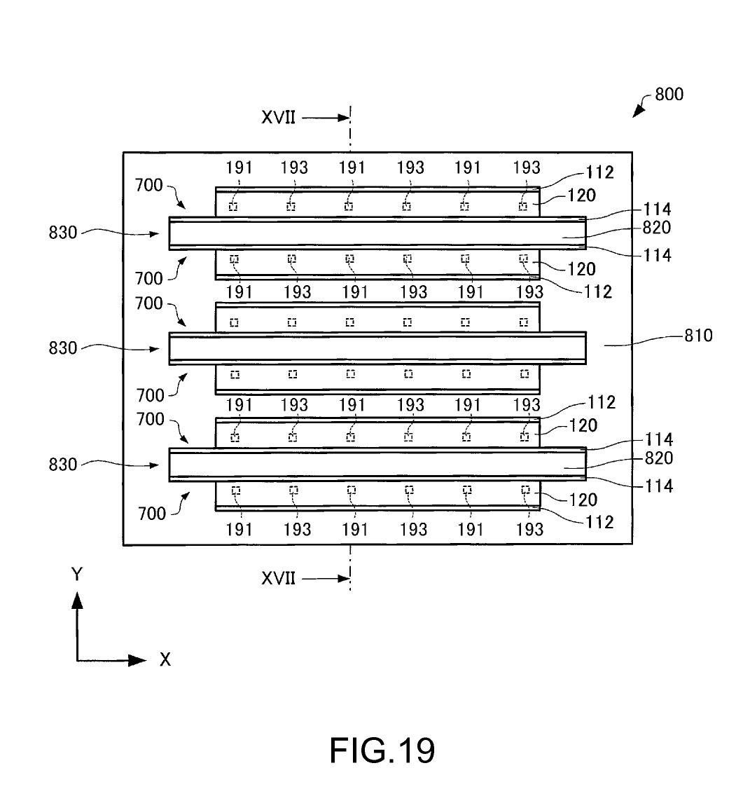

FIG. 19 is a diagram schematically showing the light source 800 of the projector 900 according to this embodiment.

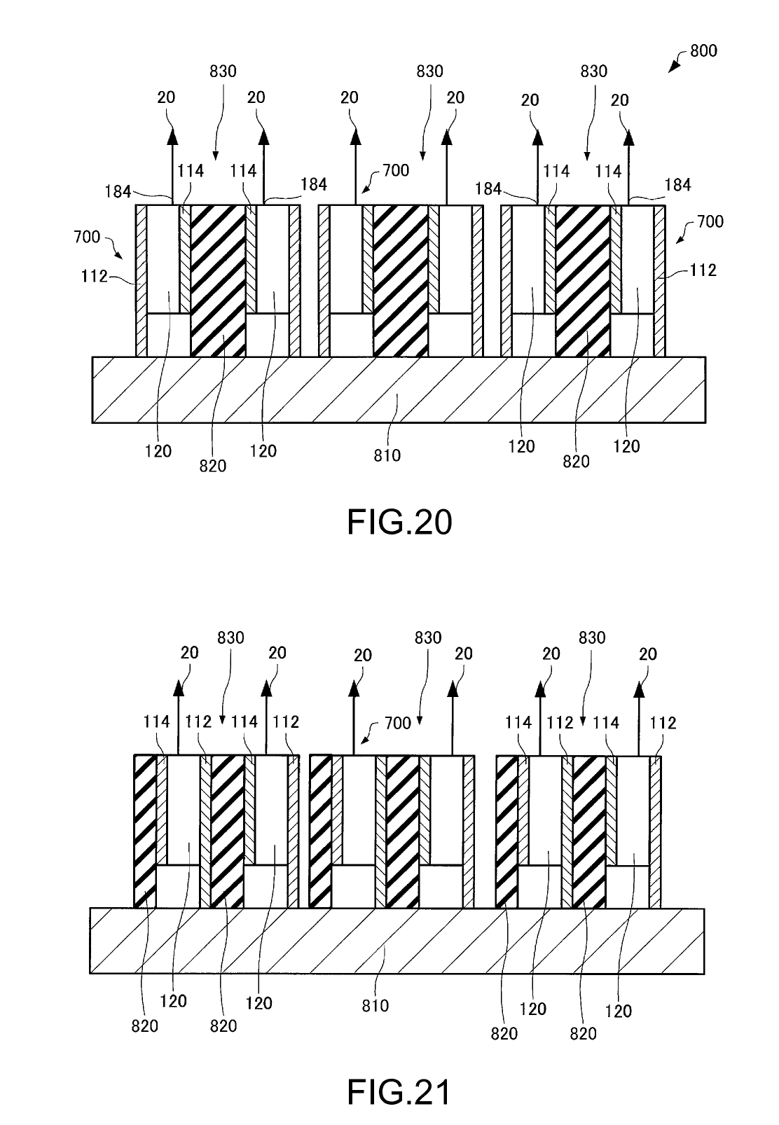

FIG. 20 is a sectional view taken along line XVII-XVII in FIG. 19 schematically showing the light source 800 of the projector 900 according to this embodiment.

The light source 800 can include, as shown in FIGS. 19 and 20, the light-emitting device 700, a base 810, and a sub-mount 820.

Two light-emitting devices 700 and the sub-mount 820 can form a structure 830. Plural structures 830 are provided. As shown in FIG. 19, the structures 830 are arranged in a direction (a Y axis direction) orthogonal to an arrangement direction (an X direction) of the end faces 191 and 193 serving as light emitting areas of the light-emitting device 700. The structures 830 can be arranged such that a distance between the light emitting areas in the X axis direction and a distance between the light emitting areas in the Y axis direction are the same. Consequently, it is possible to easily make light emitted from the light-emitting device 700 incident on the lens array 902.

The structure 830 is composed of two light-emitting devices 700 and a sub-mount 820 provided in between. In an example shown in FIGS. 19 and 20, the two light-emitting devices 700 are arranged such that second electrodes 114 are opposed to each other via the sub-mount 820. On part of the surfaces of the sub-mount 820 in contact with the second electrodes 114, for example, wires are formed. Consequently, it is possible to separately supply a voltage for each of the plural second electrodes 114. As the material of the sub-mount 820, for example, aluminum nitride and aluminum oxide can be used.

The base 810 supports the structure 830. In the example shown in FIG. 20, the base 810 is connected to the first electrodes 112 of plural light-emitting devices 700. Consequently, the base 810 can function as a common electrode of the plural first electrodes 112. As the material of the base 810, for example, copper and aluminum can be used. Although not shown in the figure, the base 810 may be connected to a heat sink via a Peltier device.

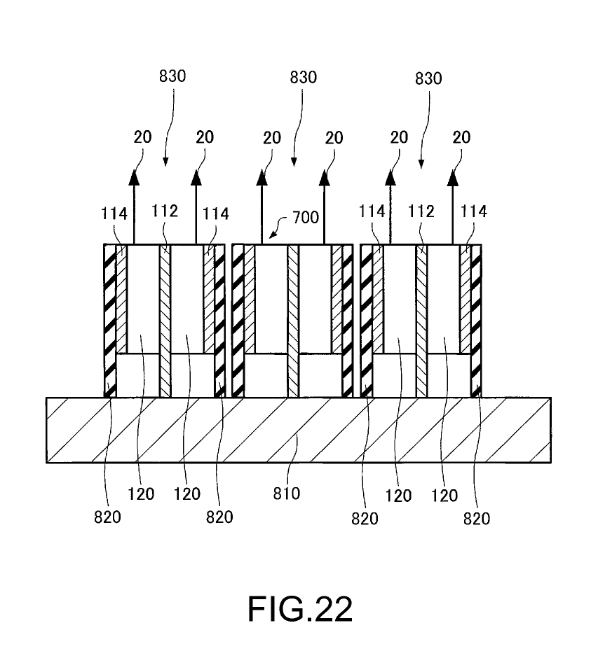

A formation of the structure 830 is not limited to the example shown in FIGS. 19 and 20. For example, as shown in FIG. 21, the two light-emitting devices 700 composing the structure 830 may be arranged such that the first electrode 112 of one light-emitting device 700 and the second electrode 114 of the other light-emitting device 700 are opposed to each other via the sub-mount 820. As shown in FIG. 22, the two light-emitting devices 700 may be arranged such that the first electrode 112 of the two light-emitting devices 700 is a common electrode.

As shown in FIG. 17, the projector 900 further includes lens arrays 902R, 902G, and 902B, transmission-type liquid crystal light valves (light modulating devices) 904R, 904G, and 904B, and a projection lens (a projecting device) 908.

Lights emitted from the light sources 800R, 800G, and 800B are respectively made incident on the lens arrays 902R, 902G, and 902B. As shown in FIG. 18, on the light source 800 side, the lens array 902 can have a flat surface 901 on which the light 20 or 22 emitted from the light emitting areas 191 or 193 is made incident. Plural flat surfaces 901 are arranged at equal intervals corresponding to the plural light emitting areas 191 and 193. The optical axes of the lights 20 and 22 can be made orthogonal to an irradiation surface 905 of the liquid crystal light valve 904 by the flat surface 901.

The lens array 902 can have a convex curved surface 903 on the liquid crystal light valve 904 side. Plural convex curved surfaces 903 are provided corresponding to the plural flat surfaces 901 and arranged at equal intervals. The lights 20 and 22, the optical axes of which are converted on the flat surfaces 901, can be condensed by the convex curved surfaces 903. The lights 20 and 22 can be superimposed (partially superimposed) by setting a diffusion angle small. Consequently, it is possible to irradiate the liquid crystal light valve 904 with high uniformity.

As explained above, the lens array 902 can control the optical axes and the diffusion angle of the lights 20 and 22 emitted from the light source 800 to superimpose the lights 20 and 22.

As shown in FIG. 17, lights superimposed by the lens arrays 902R, 902G, and 902B are respectively made incident on the liquid crystal light valves 904R, 904G, and 904B. The liquid crystal light valves 904R, 904G, and 904B respectively modulate the incident lights according to image information. The projection lens 908 expands an image formed by the liquid crystal light valves 904R, 904G, and 904B and projects the image on a screen (a display surface) 910.

The projector 900 can include a cross dichroic prism (color light combining means) 906 that combines the lights emitted from the liquid crystal light valves 904R, 904G, and 904B and leads the combined light to the projection lens 908.

Three color lights modulated by the liquid crystal light valves 904R, 904G, and 904B are made incident on the cross dichroic prism 906. The prism 906 is formed by sticking four rectangular prisms together. A dielectric multilayer film that reflects red light and a dielectric multilayer film that reflects blue light are arranged crosswise on inner surfaces of the prism 906. The three color lights are combined by these dielectric multilayer films and light representing a color image is formed. The combined light is projected on the screen 910 by the projection lens 908, which is a projection optical system. An expanded image is displayed.

The projector 900 includes the light-emitting device 700 in which a radiation pattern is satisfactory and it is possible to design distances between plural light emitting areas to a desired value while realizing a reduction in the size of the light-emitting device 700. Therefore, in the projector 900, alignment of the lens array 902 is easy and it is possible to irradiate the liquid crystal light valve 904 with high uniformity. It is possible to provide a projector reduced in size and increased in luminance.

In the example explained above, the transmissive liquid crystal light valve is used as the light modulating device. However, a light valve other than liquid crystal may be used or a reflective light valve may be used. As of such a light valve, for example, a reflective liquid crystal light valve and a digital micromirror device can be used. The formation of the projection optical system is appropriately changed according to the type of a light valve in use.

The light source 800 can also be applied to a light source device for a scanning-type image display apparatus (projector) including a means of scanning light, for displaying an image in a desired size on a display surface.

The embodiments and the modifications explained above are examples. This is not a limitation. For example, the embodiments and the modifications can be appropriately combined.

The embodiments of the invention are explained in detail above. However, those skilled in the art can easily understand that various modifications are possible without substantially departing from the new matters and the effects of the invention. Therefore, all such modifications are considered being included in the scope of the invention.

The entire disclosure of Japanese Patent Application No. 2011-084251, filed Apr. 6, 2011 is expressly incorporated by reference herein.

What is claimed is:

1. A light-emitting device comprising:
a first layer that generates light by an injection current and form a waveguide of the light;
second and third layers that hold the first layer therebetween and suppress a leak of the light; and
an electrode that injects the injection current into the first layer, wherein
the waveguide of the light obtained by the injection current includes a belt-like first region, a belt-like second region and a belt-like third region,
the first region includes a first portion having a curvature,
the second region includes a second portion having a curvature,
the first and second regions are connected in a reflecting section on a reflection surface provided on a side surface of the first layer,
the third region forms a resonator,
a distance between the third region and at least one of the first and second regions is a distance at which evanescent coupling occurs,
first light is emitted from a first light emitting area of the first region on an emission surface provided on a side surface of the first layer opposed to the reflection surface,
second light is emitted from a second light emitting area of the second region on the emission surface, and
the first light and the second light are emitted in the same direction.

2. The light-emitting device according to claim 1, wherein the reflecting section has a higher reflectance than a reflectance on the first and second light emitting areas in a wavelength band of the light generated in the first layer.

3. The light-emitting device according to claim 1, wherein
the first region is connected to the reflecting section while tilting to one side with respect to a perpendicular of the reflection surface viewed from a stacking direction of the first layer and the second layer, and
the second region is connected to the reflecting section while tilting to other side with respect to the perpendicular viewed from the stacking direction.

4. The light-emitting device according to claim 1, wherein
the first region is connected to the reflecting section while tilting at a first angle with respect to a perpendicular of the reflection surface,
the second region is connected to the reflecting section while tilting at a second angle with respect to the perpendicular, and
the first angle and the second angle are equal to or larger than a critical angle and are the same size.

5. The light-emitting device according to claim 1, wherein
the first region includes a third portion linearly provided from the first portion to the emission surface, and
the second region includes a fourth portion linearly provided from the second portion to the emission surface.

6. The light-emitting device according to claim 1, wherein
the first region includes a fifth portion linearly provided from the reflecting section to the first portion, and
the second region includes a sixth portion linearly provided from the reflecting section to the second portion.

7. The light-emitting device according to claim 1, wherein the first and second portions have an arc shape viewed from a stacking direction of the first layer and the second layer.

8. The light-emitting device according to claim 1, wherein the third region includes reflection surfaces at both ends in a longitudinal direction thereof.

9. The light-emitting device according to claim 1, wherein the third region includes a periodic structure composing a resonator of a distributed feedback type therein.

10. The light-emitting device according to claim 1, wherein the third region includes resonators employing distributed Bragg reflector at both ends in a longitudinal direction thereof.

11. The light-emitting device according to claim 1, wherein a distance between the third region and the first or second region is fixed.

12. The light-emitting device according to claim 1, wherein the third region and the first or second region are parallel.

13. The light-emitting device according to claim 1, wherein a plurality of the third regions are provided.

14. The light-emitting device according to claim 1, wherein the third region includes a waveguide structure of an index-guiding type.

15. The light-emitting device according to claim 1, wherein the first and second regions include a waveguide structure of an index-guiding type.

16. The light-emitting device according to claim 1, wherein
a fourth layer is formed on a side of the third layer opposite to the first layer side,
the light-emitting device further comprises:
a first electrode electrically connected to the second layer; and
a second electrode electrically connected to the third layer and in contact with the fourth layer,
a shape of the first, second, and third regions is the same as a shape of a contact surface of the fourth layer and the second electrode, and
the fourth layer is a layer in ohmic contact with the second electrode.

17. The light-emitting device according to claim 1, wherein the side surface on which the reflecting section is provided is a cleavage plane.

18. A projector comprising:
the light-emitting device according to claim 1;
a micro lens that condenses light emitting from the light-emitting device;
a light modulating device that modulates the light condensed by the micro lens according to image information; and
a projecting device that projects an image formed by the light modulating device.

19. A projector comprising:
the light-emitting device according to claim 2;
a micro lens that condenses light emitting from the light-emitting device;
a light modulating device that modulates the light condensed by the micro lens according to image information; and
a projecting device that projects an image formed by the light modulating device.

20. A projector comprising:
the light-emitting device according to claim 3;
a micro lens that condenses light emitting from the light-emitting device;
a light modulating device that modulates the light condensed by the micro lens according to image information; and
a projecting device that projects an image formed by the light modulating device.
